(19) United States
(12) Patent Application Publication
(10) Pub. No.: US 2025/0228072 A1
(43) Pub. Date: Jul. 10, 2025

(54) SUB-PIXEL, DISPLAY PANEL INCLUDING THE SAME, AND METHOD OF FABRICATING THE DISPLAY PANEL

(71) Applicant: Samsung Display Co., LTD., Yongin-si (KR)

(72) Inventors: Keun Woo KIM, Yongin-si (KR); Doo Na KIM, Yongin-si (KR); Sang Sub KIM, Yongin-si (KR); Bum Mo SUNG, Yongin-si (KR); Jun Hyung LIM, Yongin-si (KR); Sang Gun CHOI, Yongin-si (KR)

(21) Appl. No.: 18/777,454

(22) Filed: Jul. 18, 2024

(30) Foreign Application Priority Data
Jan. 5, 2024 (KR) 10-2024-0002068

(51) Int. Cl. H10K 59/121; H01L 29/417; H01L 29/66; H01L 29/786; H10K 59/12; H10K 59/131

(52) U.S. Cl. CPC H10K 59/1213; H10D 30/0321; H10D 30/6729; H10D 30/6755; H10K 59/1201; H10K 59/131

(57) ABSTRACT

A display panel includes: a silicon substrate; a first active pattern including a single-crystalline semiconductor layer on the silicon substrate; a first gate insulating layer covering the first active pattern; a first gate electrode on the first gate insulating layer, and including at least a portion overlapping with the first active pattern; a first interlayer insulating layer on the first gate electrode; a second active pattern on the first interlayer insulating layer, and including a metal oxide semiconductor; a second gate insulating layer covering the second active pattern; a second gate electrode on the second gate insulating layer, and including at least a portion overlapping with the second active pattern; a second interlayer insulating layer covering the second gate electrode; and a source/drain electrode layer on the second interlayer insulating layer, and connected to the first and second active patterns.

### CROSS-REFERENCE TO RELATED APPLICATION

The present application claims priority to and the benefit of Korean Patent Application Number 10-2024-0002068, filed on Jan. 5, 2024, in the Korean Intellectual Property Office, the entire disclosure of which is incorporated by reference herein.

### BACKGROUND

### 1. Field

Aspects of embodiments of the present disclosure relate to a sub-pixel, a display panel including the sub-pixel, and a method of fabricating the display panel.

### 2. Description of the Related Art

With the development of information technology, the importance of a display device, which is a connection medium between a user and information, has been emphasized. Owing to the importance of display devices, the use of various kinds of display devices, such as a liquid crystal display device and an organic light-emitting display device, has increased.

As the display device becomes smaller, approaches to increase the resolution of the display device has been studied from multiple angles.

In addition, it may be desired to reduce power consumption by reducing the magnitude of a leakage current in the display device (e.g., in sub-pixels thereof), and to improve a display quality by displaying images at various frequencies.

The above information disclosed in this Background section is for enhancement of understanding of the background of the present disclosure, and therefore, it may contain information that does not constitute prior art.

### SUMMARY

Embodiments of the present disclosure may be directed to a sub-pixel, a display panel including the sub-pixel, and a method of fabricating the display panel, in which images may be displayed at various suitable frame rates with a high resolution and reduced power consumption.

According to one or more embodiments of the present disclosure, a display panel includes: a silicon substrate; a first active pattern including a single-crystalline semiconductor layer on the silicon substrate; a first gate insulating layer covering the first active pattern; a first gate electrode on the first gate insulating layer, and including at least a portion overlapping with the first active pattern; a first interlayer insulating layer on the first gate electrode; a second active pattern on the first interlayer insulating layer, and including a metal oxide semiconductor; a second gate insulating layer covering the second active pattern; a second gate electrode on the second gate insulating layer, and including at least a portion overlapping with the second active pattern; a second interlayer insulating layer covering the second gate electrode; and a source/drain electrode layer on the second interlayer insulating layer, and connected to the first and second active patterns.

In an embodiment, the silicon substrate may include a buffer layer including silicon oxide, and the first active pattern may be located on the buffer layer.

In an embodiment, the first active pattern may be part of a semiconductor of a P-type transistor, and the second active pattern may be part of a semiconductor of an N-type transistor.

In an embodiment, the display panel may include a plurality of sub-pixels, and each of the plurality of sub-pixels may include at least one light emitting element.

At least one of the plurality of sub-pixels may further include: a driving transistor including a semiconductor layer, a first electrode connected to a first node, a gate electrode connected to a second node, and a second electrode connected to a third node, the driving transistor being configured to control a magnitude of a current flowing through the light emitting element based on a voltage applied to the second node; and a compensation transistor including a semiconductor layer, and configured to switch an electrical connection between the first node and the second node. The semiconductor layer of the driving transistor may include the first active pattern, and the semiconductor layer of the compensation transistor may include the second active pattern.

In an embodiment, a gate electrode of the compensation transistor may be connected to a sub-gate line.

In an embodiment, the sub-gate line may include the source/drain electrode layer.

In an embodiment, the sub-gate line may be directly located on the silicon substrate, and the source/drain electrode layer may include a connection electrode configured to electrically connect the sub-gate line and the second active pattern to each other.

In an embodiment, the at least one of the plurality of sub-pixels may further include an initialization transistor including a semiconductor layer, and configured to switch an electrical connection between the second node and a power line configured to be applied with an initialization voltage, and the semiconductor layer of the initialization transistor may include the second active pattern.

In an embodiment, a gate electrode of the initialization transistor may be connected to a sub-gate line.

In an embodiment, the sub-gate line may include the source/drain electrode layer.

In an embodiment, the sub-gate line may be directly located on the silicon substrate, and the source/drain electrode layer may include a connection electrode configured to electrically connect the sub-gate line and the second active pattern to each other.

In an embodiment, the source/drain electrode layer may include a first source/drain electrode layer, and the display panel may include: a first via layer covering the first source/drain electrode layer; a second source/drain electrode layer on the first via layer, and connected to the first source/drain electrode layer through a contact hole; and a second via layer covering the second source/drain electrode layer.

In an embodiment, the power line may include the second source/drain electrode layer.

In an embodiment, the power line may be directly located on the silicon substrate, and the source/drain electrode layer may include a connection electrode configured to electrically connect the power line and the second active pattern to each other.

According to one or more embodiments of the present disclosure, a sub-pixel includes: a light emitting element; and a sub-pixel circuit configured to supply a current to the light emitting element. The sub-pixel circuit includes: a driving transistor including a first active pattern having a single-crystalline structure on a silicon substrate and connected to a first node and a third node, and a first gate electrode connected to a second node and including at least a portion overlapping with the first active pattern, the driving transistor being configured to provide a current corresponding to a voltage applied to the second node; and a compensation transistor including a second active pattern including a metal oxide semiconductor layer, and a second gate electrode including at least a portion overlapping with the second active pattern, the compensation transistor being configured to switch an electrical connection between the first node and the second node.

In an embodiment, the first active pattern may be part of a semiconductor of a P-type transistor, and the second active pattern may be part of a semiconductor of an N-type transistor.

According to one or more embodiments of the present disclosure, a method of fabricating a display panel, includes: forming a first active pattern having a single-crystalline structure on a silicon substrate; forming a first gate insulating layer on the first active pattern; forming a first gate electrode including at least a portion overlapping with the first active pattern; forming a first interlayer insulating layer on the first gate electrode; forming a second active pattern including a metal oxide semiconductor on the first interlayer insulating layer; forming a second gate insulating layer on the second active pattern; forming, on the second gate insulating layer, a second gate electrode including at least a portion overlapping with the second active pattern; forming a second interlayer insulating layer on the second gate electrode; and forming, on the second interlayer insulating layer, a source/drain electrode layer connected to the first and second active patterns.

In an embodiment, the method may further include forming a buffer layer by injecting oxygen ions into the silicon substrate, and the first active pattern may be formed on the buffer layer.

In an embodiment, the forming of the first active pattern may include doping a P-type impurity, and the forming of the second active pattern may include doping an N-type impurity.

In an embodiment, the method may further include directly forming a power line or a sub-gate line on the silicon substrate, and the forming of the source/drain electrode layer may include at least one of: connecting the second active pattern and the power line to each other; or connecting the second active pattern and the sub-gate line to each other.

### BRIEF DESCRIPTION OF THE DRAWINGS

The above and other aspects and features of the present disclosure will be more clearly understood from the following detailed description of the illustrative, non-limiting embodiments with reference to the accompanying drawings.

FIG. 1 is a system block diagram of a display device in accordance with one or more embodiments of the present disclosure.

FIG. 2 is a block diagram illustrating an embodiment of any one sub-pixel of FIG. 1.

FIG. 3 is an equivalent circuit diagram in accordance with an embodiment of the sub-pixel of FIG. 2.

FIG. 4 is a plan view in accordance with an embodiment of a display panel of FIG. 1.

FIG. 5 is an exploded perspective view illustrating a portion of the display panel of FIG. 4.

FIG. 6 is a plan view illustrating an embodiment of any one pixel of FIG. 5.

FIG. 7 illustrates a cross-sectional view taken along the line I-I′ of FIG. 6.

FIGS. 8-21 illustrate a method of fabricating the display panel in accordance with one or more embodiments of the present disclosure.

FIG. 22 is a cross-sectional view illustrating an embodiment of an emission structure of FIG. 7.

FIG. 23 is a cross-sectional view illustrating another embodiment of the emission structure of FIG. 7.

FIG. 24 is a plan view illustrating another embodiment of any one pixel of FIG. 5.

FIG. 25 is a plan view illustrating another embodiment of any one pixel of FIG. 5.

FIG. 26 is a diagram illustrating an example of a display system in accordance with one or more embodiments of the present disclosure.

FIG. 27 is a perspective view illustrating an application example of the display system of FIG. 26.

FIG. 28 is a diagram illustrating a head-mounted display that is worn on a user.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Furthermore, as used herein, the expression “being the same” may mean “being substantially the same”. In other words, the expression “being the same” may include a range that may be tolerated by those skilled in the art. Other expressions may also be expressions from which “substantially” has been omitted.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

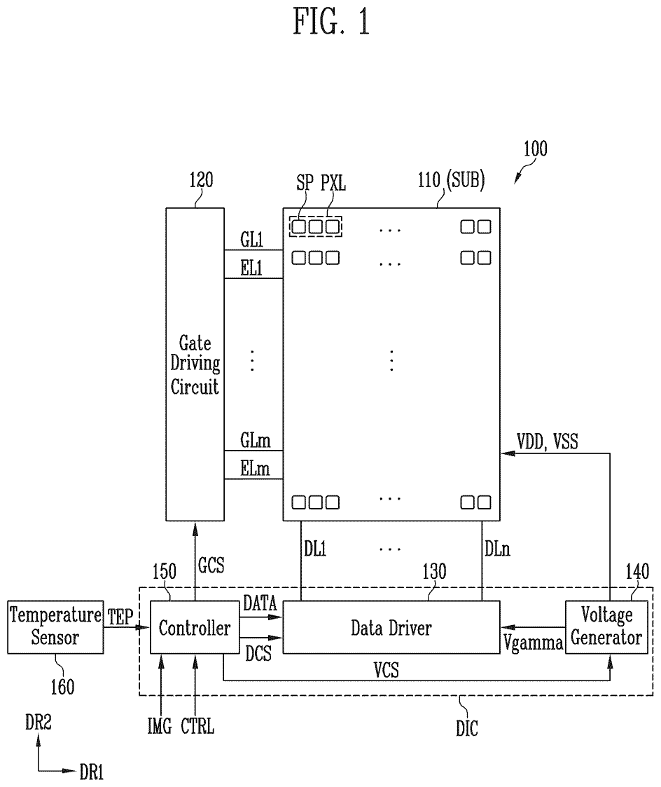

FIG. 1 is a system block diagram of a display device 100 in accordance with one or more embodiments of the present disclosure.

Referring to FIG. 1, the display device 100 in accordance with one or more embodiments of the present disclosure may include a display panel 110, a gate driving circuit 120, a data driver 130, a voltage generator 140, a controller 150, and a temperature sensor 160.

The display panel 110 may include a plurality of sub-pixels SP. First to m-th gate lines GL1 to GLm (where m is an integer of 2 or more) that are connected to the plurality of sub-pixels SP may be disposed on the display panel 110. First to n-th data lines DL1 to DLn (where n is an integer of 2 or more) that are connected to the plurality of sub-pixels SP may be disposed on the display panel 110.

The plurality of sub-pixels SP may be connected (e.g., electrically connected) to the gate driving circuit 120 by the first to m-th gate lines GL1 to GLm. The plurality of sub-pixels SP may be connected (e.g., electrically connected) to the data driver 130 by the first to n-th data lines DL1 to DLn.

Each of the plurality of sub-pixels SP may include at least one light emitting element to generate light. Each of the plurality of sub-pixels SP may generate light in a desired color (e.g., a specific or predetermined color or wavelength band), such as red, green, blue, cyan, magenta, or yellow. Two or more sub-pixels from among the plurality of sub-pixels SP may form one pixel PXL. For example, as illustrated in FIG. 1, three sub-pixels SP may form one pixel PXL.

The gate driving circuit 120 may be connected (e.g., electrically connected) to the plurality of sub-pixels SP (e.g., the plurality of sub-pixels SP arranged generally along a first direction DR1) by the first to m-th gate lines GL1 to GLm. The first direction DR1 may be, for example, a direction crossing from one side (e.g., a left side) of the display panel 110 to another side (e.g., a right side) of the display panel 110. The first direction DR1 may be, for example, a row direction.

The gate driving circuit 120 may output gate signals (e.g., gate signals of a turn-on level or a turn-off level) to the first to m-th gate lines GL1 to GLm in response to a gate control signal GCS. In one or more embodiments, the gate control signal GCS may include a start signal for instructing each frame to start, a horizontal synchronization signal for outputting gate signals in synchronization with a timing at which data signals are applied, and the like.

In one or more embodiments, first to m-th emission control lines EL1 to ELm that are connected to the plurality of sub-pixels SP may be further disposed on the display panel 110. The first to m-th emission control lines EL1 to ELm may be disposed to extend in the row direction on the display panel 110. The plurality of sub-pixels SP may be connected (e.g., electrically connected) to the first to m-th emission control lines EL1 to ELm. In the present embodiment, the gate driving circuit 120 may include an emission control driver to control the first to m-th emission control lines EL1 to ELm. The emission control driver may be operated under control of the controller 150.

The gate driving circuit 120 may be disposed on one side of the display panel 110. However, the present disclosure is not limited thereto. For example, the gate driving circuit 120 may be divided into two or more driving circuits that are physically and/or logically distinguished from each other. The driving circuits may be disposed on a first side of the display panel 110 and a second side (e.g., a second side of the display panel 110 opposite to the first side). As such, the gate driving circuit 120 may be disposed in the display panel 110 or around (e.g., adjacent to) the display panel 110 in various suitable forms as needed or desired.

The data driver 130 may be connected (e.g., electrically connected) to the plurality of sub-pixels SP (e.g., the plurality of sub-pixels SP arranged generally along a second direction DR2) by the first to n-th data lines DL1 to DLn. The second direction DR2 may be, for example, a direction crossing from one side (e.g., a lower side) of the display panel 110 to another side (e.g., an upper side) of the display panel 110. The second direction DR2 may cross or intersect the first direction DR1. The second direction DR2 may be, for example, a column direction.

The data driver 130 may receive image data DATA and a data control signal DCS from the controller 150. The data driver 130 may be operated in response to the data control signal DCS. In one or more embodiments, the data control signal DCS may include a source start pulse, a source shift clock, a source output enable signal, and the like.

The data driver 130 may apply, using voltages (e.g., gamma voltages Vgamma) from the voltage generator 140, data signals having grayscale voltages (e.g., gray level voltages) corresponding to the image data DATA to the first to n-th data lines DL1 to DLn. When a gate signal (e.g., a gate signal having a turn-on level) is applied to each of the first to m-th gate lines GL1 to GLm, the data signals corresponding to the image data DATA may be applied to the data lines DL1 to DLm. Each of the plurality of sub-pixels SP may receive a data signal applied thereto at a corresponding timing, in response to a gate signal (e.g., a gate signal having a turn-on level). Each of the plurality of sub-pixels SP may generate light corresponding to the inputted data signal. As a result, an image may be displayed on the display panel 110.

In one or more embodiments, each of the gate driving circuit 120 and the data driver 130 may include complementary metal-oxide semiconductor (CMOS) circuit elements.

The voltage generator 140 may operate in response to a voltage control signal VCS provided from the controller 150. The voltage generator 140 may generate a plurality of voltages, and may provide the generated voltages to the components of the display device 100. For example, the voltage generator 140 may receive an input voltage from an external device provided outside the display device 100. The voltage generator 140 may control (e.g., may reduce) the level of the received voltage, and may regulate the voltage adjusted in level. The voltage generator 140 may generate a plurality of voltages.

The voltage generator 140 may generate, for example, a first power voltage VDD, a second power voltage VSS, a gamma voltage Vgamma, and the like. The generated first and second power voltages VDD and VSS may be applied (e.g., applied in common) to the plurality of sub-pixels SP. The first power voltage VDD may have a relatively high voltage level. The second power voltage VSS may have a voltage level lower than that of the first power voltage VDD. The generated gamma voltage Vgamma may be provided to the data driver 130. In other embodiments, the first power voltage VDD and/or the second power voltage VSS may be provided from an external device (e.g., a power management integrated circuit (PMIC)) of the display device 100.

In one or more embodiments, the voltage generator 140 may generate other voltages. For example, the voltage generator 140 may generate an initialization voltage to be applied (e.g., applied in common) to the plurality of sub-pixels SP. For example, during a sensing operation for sensing electrical characteristics of transistors and/or a light emitting element(s) of the plurality of sub-pixels SP, a reference voltage (e.g., a certain or predetermined reference voltage) may be applied to each of the first to n-th data lines DL1 to DLn. The voltage generator 140 may generate the reference voltage.

The controller 150 may control overall operations of the display device 100. The controller 150 may receive input image data IMG and a control signal CTRL from an external device for controlling an operation of displaying the input image data IMG. The controller 150 may provide a gate control signal GCS, a data control signal DCS, a voltage control signal VCS, and the like in response to the received control signal CTRL.

The controller 150 may convert the input image data IMG to be suitable for the display device 100 or the display panel 110, and then output the image data DATA. In one or more embodiments, the controller 150 may align the input image data IMG to be suitable for the sub-pixels SP on a row basis, and then output the image data DATA.

Two or more components from among the data driver 130, the voltage generator 140, and the controller 150 may be mounted on a single integrated circuit. As illustrated in FIG. 1, the data driver 130, the voltage generator 140, and the controller 150 may be included in a driver integrated circuit DIC. In this case, the data driver 130, the voltage generator 140, and the controller 150 may be components that are functionally separated from each other in the single driver integrated circuit DIC. In other embodiments, at least one of the data driver 130, the voltage generator 140, and/or the controller 150 may be mounted on the driver integrated circuit DIC, and another remaining one may be mounted on an integrated circuit different from the driver integrated circuit DIC.

The temperature sensor 160 may sense a temperature (e.g., a peripheral temperature), and may generate temperature data TEP indicating the sensed temperature. In an embodiment, the temperature sensor 160 may be disposed on the display panel 110. In an embodiment, the temperature sensor 160 may be disposed adjacent to the display panel 110 and/or the driver integrated circuit DIC. In an embodiment, the display device 100 may include two or more temperature sensors 160.

The controller 150 may control various operations of the display device 100 in response to the temperature data TEP. In one or more embodiments, the controller 150 may adjust the luminance of an image output from the display panel 110 in response to the temperature data TEP. For example, the controller 150 may control components such as the data driver 130 and/or the voltage generator 140, and thus, may adjust at least one of the data signals, the first power voltage VDD, and/or the second power voltage VSS to be input to the display panel 110.

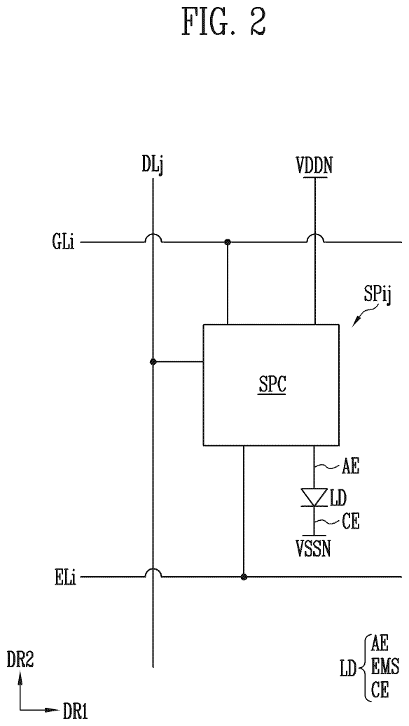

FIG. 2 is a block diagram illustrating an embodiment of any one sub-pixel SPij from among the sub-pixels SP of FIG. 1.

In FIG. 2, the sub-pixel SPij is illustrated as being disposed at (e.g., in or on) an i-th row (where i is an integer equal to or greater than 1 and less than or equal to m) and a j-th column (where j is an integer equal to or greater than 1 and less than or equal to n) from among the plurality of sub-pixels SP illustrated in FIG. 1.

Referring to FIG. 2, the sub-pixel SPij may include a sub-pixel circuit SPC and a light emitting element LD.

The light emitting element LD may be connected (e.g., electrically connected) between a first power voltage node VDDN and a second power voltage node VSSN. The first power voltage node VDDN may be a node to which the first power voltage VDD (e.g., see FIG. 1) is applied. The second power voltage node

VSSN may be a node to which the second power voltage VSS (e.g., see FIG. 1) is applied.

The light emitting element LD may include a first electrode, an emission structure EMS, and a second electrode. The first electrode may be any one of an anode electrode AE and/or a cathode electrode CE of the light emitting element LD.

The second electrode may be the other one of the anode electrode AE and/or the cathode electrode CE of the light emitting element LD. Hereinafter, for convenience, an example in which the first electrode of the light emitting element LD is the anode electrode AE and the second electrode of the light emitting element LD is the cathode electrode CE may be described in more detail.

The anode electrode AE of the light emitting element LD may be connected (e.g., electrically connected) to the first power voltage node VDDN through the sub-pixel circuit SPC. The cathode electrode CE of the light emitting element LD may be connected (e.g., electrically connected) to the second power voltage node VSSN. For example, the anode electrode AE of the light emitting element LD may be connected (e.g., electrically connected) to the first power voltage node VDDN through one or more transistors included in the sub-pixel circuit SPC.

The sub-pixel circuit SPC of the sub-pixel SPij may be connected (e.g., electrically connected) to an i-th gate line GLi from among the first to m-th gate lines GL1 to GLm (e.g., see FIG. 1). The sub-pixel circuit SPC of the sub-pixel SPij may be connected (e.g., electrically connected) to an i-th emission control line ELi from among the first to m-th emission control lines EL1 to ELm (e.g., see FIG. 1). The sub-pixel circuit SPC of the sub-pixel SPij may be connected (e.g., electrically connected) to a j-th data line DLj from among the first to n-th data lines DL1 to DLn (e.g., see FIG. 1). The sub-pixel circuit SPC may control the emission timing and/or emission luminance of the light emitting element LD according to (e.g., in response to) signals received through the signal lines.

The sub-pixel circuit SPC may operate in response to a gate signal received through the i-th gate line GLi. The sub-pixel circuit SPC may operate in response to an emission control signal received through the i-th emission control line ELi.

The sub-pixel circuit SPC may receive a data signal through a j-th data line DLj. The sub-pixel circuit SPC may store a voltage of the data signal (e.g., a voltage corresponding to the data signal) in response to a gate signal (e.g., a gate signal having a turn-on level) received through the i-th gate line GLi. The sub-pixel circuit SPC may adjust the timing at which current flows to the light emitting element LD in response to an emission control signal (e.g., an emission control signal having a turn-on level) applied through the i-th emission control line ELi. The magnitude of the current flowing to the light emitting element LD may vary depending on the voltage stored in the sub-pixel circuit SPC. The light emitting element LD may emit light having a luminance corresponding to the data signal.

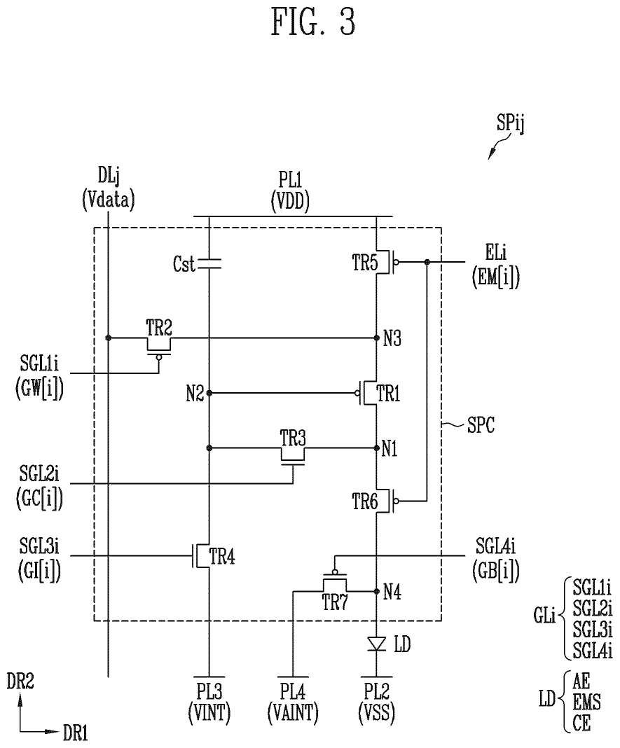

FIG. 3 is an equivalent circuit diagram in accordance with an embodiment of the sub-pixel SPij of FIG. 2.

Referring to FIG. 3, the sub-pixel SPij in accordance with one or more embodiments of the present disclosure may include the sub-pixel circuit SPC and the light emitting element LD.

The sub-pixel circuit SPC may be connected (e.g., electrically connected) to the i-th gate line GLi (hereinafter, abbreviated as “gate line GLi”), the i-th emission control line ELi (hereinafter, abbreviated as “emission control line ELi”), and the j-th data line DLj (hereinafter, abbreviated as “data line DLj”).

The gate line GLi may include two or more sub-gate lines. Referring to FIG. 3, the gate line GLi may include an i-th first sub-gate line SGL1i (e.g., abbreviated as “first sub-gate line SGL1i”), an i-th second sub-gate line SGL2i (e.g., abbreviated as “second sub-gate line SGL2i”), an i-th third sub-gate line SGL3i (e.g., abbreviated as “third sub-gate line SGL3i”), an i-th fourth sub-gate line SGL4i (e.g., abbreviated as “fourth sub-gate line SGL4i”).

The sub-pixel circuit SPC in accordance with one or more embodiments of the present disclosure may include a plurality of switching elements. For example, the sub-pixel circuit SPC may include first to seventh transistors TR1 to TR7. The sub-pixel circuit SPC in accordance with one or more embodiments of the present disclosure may include at least one storage element. For example, the sub-pixel circuit SPC may include a storage capacitor Cst.

The first transistor TR1 may control the magnitude of a current (e.g., a driving current) to be supplied to the light emitting element LD. The first transistor TR1 may include a first electrode connected (e.g., electrically connected) to a first node N1, a second electrode connected (e.g., electrically connected) to a third node N3, and a gate electrode connected (e.g., electrically connected) to a second node N2. Depending on the magnitude of a voltage applied to the second node N2, the magnitude of the current (e.g., the driving current) flowing through the first transistor TR1 may be determined. The first electrode of the first transistor TR1 may be either a source electrode or a drain electrode (e.g., such as the drain electrode), and the second electrode may be a remaining one of the source electrode or the drain electrode (e.g., such as the source electrode). The first transistor TR1 may be referred to as a driving transistor.

The second transistor TR2 may write a data voltage Vdata to the sub-pixel circuit SPC. The second transistor TR2 may switch an electrical connection between the data line DLj and the third node N3. The second transistor TR2 may include a gate electrode connected (e.g., electrically connected) to the first sub-gate line SGL1i. The second transistor TR2 may electrically connect the data line DLj and the third node N3 to each other in response to a first scan signal GW [i] (e.g., the first scan signal GW [i] having a turn-on level) applied to the first sub-gate line SGL1i. The second transistor TR2 may be referred to as a scan transistor.

The third transistor TR3 may switch an electrical connection between the first node N1 and the second node N2. The third transistor TR3 may compensate for a change in a characteristic value (e.g., a change in a threshold voltage) of the first transistor TR1. The third transistor TR3 may include a gate electrode connected (e.g., electrically connected) to the second sub-gate line SGL2i. The third transistor TR3 may electrically connect the first node N1 and the second node N2 to each other in response to a second scan signal GC [i] (e.g., the second scan signal GC [i] having a turn-on level) applied to the second sub-gate line SGL2i. When the third transistor TR3 is turned on, the first transistor TR1 may be connected in the form of a diode (e.g., may be diode connected). The third transistor TR3 may be referred to as a compensation transistor.

The fourth transistor TR4 may switch an electrical connection between the second node N2 and a third power line PL3. The fourth transistor TR4 may include a gate electrode connected (e.g., electrically connected) to the third sub-gate line SGL3i. The fourth transistor TR4 may electrically connect the second node N2 and the third power line PL3 to each other in response to a third scan signal GI [i] (e.g., the third scan signal GI [i] having a turn-on level) applied to the third sub-gate line SGL3i. When the fourth transistor TR4 is turned on, a first initialization voltage VINT supplied to the third power line PL3 may be applied to the second node N2. The fourth transistor TR4 may be referred to as a “first initialization transistor”.

The fifth transistor TR5 may switch an electrical connection between a first power line PL1 and the third node N3. The fifth transistor TR5 may include a gate electrode connected (e.g., electrically connected) to the emission control line ELi. The fifth transistor TR5 may electrically connect the first power line PL1 and the third node N3 to each other in response to an emission control signal EM [i] (e.g., the emission control signal EM [i] having a turn-on level) applied to the emission control line ELi.

When the fifth transistor TR5 is turned on, a first power voltage VDD supplied to the first power line PL1 may be applied to the third node N3. The fifth transistor TR5 may be referred to as a “first emission control transistor”.

The sixth transistor TR6 may switch an electrical connection between the first node N1 and a fourth node N4. The sixth transistor TR6 may include a gate electrode connected (e.g., electrically connected) to the emission control line ELi. The sixth transistor TR6 may electrically connect the first node N1 and the fourth node N4 to each other in response to the emission control signal EM [i] (e.g., the emission control signal EM [i] having a turn-on level) applied to the emission control line ELi. When the sixth transistor TR6 is turned on, the first node N1 and the fourth node N4 may be electrically connected to each other. The sixth transistor TR6 may be referred to as a “second emission control transistor”.

The seventh transistor TR7 may switch an electrical connection between the fourth node N4 and a fourth power line PL4. The seventh transistor TR7 may include a gate electrode connected (e.g., electrically connected) to the fourth sub-gate line SGL4i. The seventh transistor TR7 may electrically connect the fourth node N4 and the fourth power line PL4 to each other in response to a fourth scan signal GB [i] (e.g., the fourth scan signal GB [i] having a turn-on level) applied to the fourth sub-gate line SGL4i. When the seventh transistor TR7 is turned on, a second initialization voltage VAINT supplied to the fourth power line PL4 may be applied to the fourth node N4. The seventh transistor TR7 may be referred to as a “second initialization transistor”.

The storage capacitor Cst may maintain or substantially maintain the magnitude of a voltage applied to the second node N2. The storage capacitor Cst may include a first side electrode connected (e.g., electrically connected) to the first power line PL1, and a second side electrode connected (e.g., electrically connected) to the second node N2. The storage capacitor Cst may maintain or substantially maintain a difference in a potential between the second node N2 and the first power line PL1. The light emitting element LD may include a first electrode connected (e.g.,

electrically connected) to the fourth node N4, a second electrode connected (e.g., electrically connected) to a second power line PL2, and an emission structure EMS positioned between the first electrode and the second electrode. The first electrode may be any one of an anode electrode AE and/or a cathode electrode CE (e.g., such as the anode electrode AE). The second electrode may be a remaining one of the anode electrode AE and/or the cathode electrode CE (e.g., such as the cathode electrode CE). For convenience, an example in which the first electrode is the anode electrode AE and the second electrode is the cathode electrode CE may be described in more detail hereinafter. However, it should be understood that the present disclosure is not limited thereto. The first electrode (e.g., the anode electrode AE) of the light emitting element LD may be connected (e.g., electrically connected) to the first power line PL1 through the sub-pixel circuit SPC. The second electrode (e.g., the cathode electrode CE) of the light emitting element LD may be connected (e.g., electrically connected) to the second power line PL2.

The transistors TR1 to TR7 in accordance with one or more embodiments of the present disclosure may include a transistor including a P-type semiconductor, and a transistor including an N-type semiconductor. For example, referring to FIG. 3, each of the first, second, and fifth to seventh transistors TR1, TR2, TR5, TR6, and TR7 may be a transistor including a P-type semiconductor, and each of the third and fourth transistors TR3 and TR4 may be a transistor including an N-type semiconductor.

In one or more embodiments of the present disclosure, a transistor including the P-type semiconductor may include a single-crystalline silicon semiconductor. For example, the transistor including the P-type semiconductor may be directly formed on the substrate (e.g., a silicon substrate). Because the P-type semiconductor may be directly formed on the substrate, the degree of integration of the sub-pixel pixel SPC may be enhanced. For example, the P-type semiconductor may be formed directly on an epitaxial layer of the substrate (e.g., a silicon wafer substrate).

In one or more embodiments of the present disclosure, the transistor including the N-type transistor may include an oxide semiconductor. For example, the transistor including the N-type semiconductor may be provided in the form of a thin film transistor (TFT) on the substrate (e.g., a silicon substrate), with at least one insulating layer interposed therebetween from the substrate. In one or more embodiments of the present disclosure, each of the third and fourth transistors TR3 and TR4 connected (e.g., electrically connected) to the gate electrode of the first transistor TR1 may include an oxide semiconductor. Accordingly, the magnitude of a leakage current flowing through the third and fourth transistors TR3 and TR4 may be reduced. The transistor including the N-type semiconductor may be implemented using a thin film transistor (TFT) including a metal oxide semiconductor. In accordance with one or more embodiments of the present disclosure, the TFT may be formed on the silicon substrate. The transistor including the metal oxide semiconductor may have a relatively smaller leakage current. As such, power consumption may be improved, and an image may be displayed at various frame rates.

However, it may be difficult to directly form polycrystalline silicon on a silicon substrate (e.g., a silicon wafer substrate). For example, an annealing process of irradiating an excimer laser to form polycrystalline silicon may be performed. However, in the case where the excimer laser is directly irradiated onto the silicon wafer substrate, the silicon wafer substrate may be damaged. In other words, it may be difficult for those having ordinary skill in the art to form a low temperature polycrystalline silicon (LTPO) semiconductor on a silicon substrate, or to directly form an LTPO semiconductor. As such, the transistor including the P-type semiconductor may be formed to include a single-crystalline silicon (Si) semiconductor.

At least one of the first to seventh transistors TR1 to TR7 may be a metal oxide silicon field effect transistor (MOSFET).

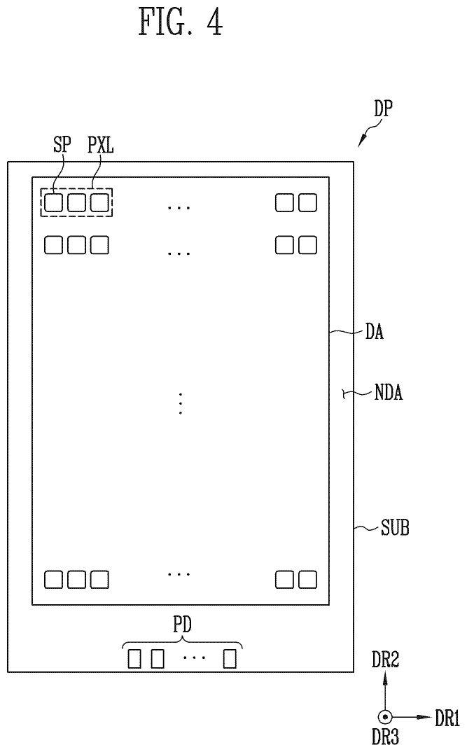

FIG. 4 is a plan view in accordance with an embodiment of the display panel 110 of FIG. 1.

A display panel DP illustrated FIG. 4 may be applied to the display panel 110 (e.g., see FIG. 1).

Referring to FIG. 4, the display panel DP may include a display area DA and a non-display area NDA. The display panel DP may display an image through the display area DA. The non-display area NDA may be disposed around a periphery (e.g., an edge area) of the display area DA.

The display panel DP may include a substrate SUB, a plurality of sub-pixels SP disposed (e.g., formed) on the substrate SUB, and a plurality of pads PD disposed (e.g., formed) on the substrate SUB. In a case where the display panel DP in accordance with one or more

embodiments of the present disclosure is used as a display screen for a head-mounted display (HMD), a virtual reality (VR) device, a mixed reality (MR) device, an augmented reality (AR) device, and the like, the display panel DP may be positioned to be close (e.g., very close) to the eyes of the user. As such, in an embodiment, the sub-pixels SP may be integrated at a relatively high density. To increase the degree of integration of the sub-pixels SP, the substrate SUB in accordance with one or more embodiments of the present disclosure may be provided as a silicon substrate. The sub-pixels SP and/or the display panel DP may be formed on the substrate SUB that is a silicon substrate. The display device 100 (e.g., refer to FIG. 1) including the display panel DP formed on the substrate SUB that is a silicon substrate may be referred to as an OLED on Silicon (OLEDOS) display device.

The plurality of sub-pixels SP may be disposed in the display area DA on the substrate SUB. Referring to FIG. 4, the sub-pixels SP may be arranged in the form of a matrix along a first direction DR1 and a second direction DR2 crossing or intersecting with the first direction DR1. However, the present disclosure is not limited thereto. For example, the sub-pixels SP in accordance with an embodiment of the present disclosure may be arranged in a zigzag pattern along the first direction DR1 and the second direction DR2. For example, the plurality of sub-pixels SP may be arranged in the form of an RGGB arrangement (e.g., a PENTILE® arrangement, PENTILE® being a duly registered trademark of Samsung Display Co., Ltd.). The first direction DR1 may refer to a row direction, and the second direction DR2 may refer to a column direction. Two or more sub-pixels SP from among the plurality of sub-pixels SP may form one pixel PXL.

Components for controlling the sub-pixels SP may be disposed in the non-display area NDA on the substrate SUB. For example, lines such as the m-th gate lines GL1 to GLm and the first to n-th data lines DL1 to DLn (e.g., see FIG. 1) may be disposed to extend to at least a portion of the non-display area NDA.

At least one of the gate driving circuit 120, the data driver 130, the voltage generator 140, the controller 150, and/or the temperature sensor 160 (e.g., see FIG. 1) may be disposed (e.g., integrally disposed) in the non-display area NDA of the display panel DP.

In an embodiment, the gate driving circuit 120 (e.g., see FIG. 1) may be formed and disposed in the non-display area NDA on the display panel DP. In an embodiment, the gate driving circuit 120 may be implemented as a separate integrated circuit distinguished from the display panel DP, and mounted in the non-display area NDA.

In an embodiment, the temperature sensor 160 (e.g., see FIG. 1) may be positioned in the non-display area NDA to sense the temperature of the display panel DP. For example, the temperature sensor 160 may be disposed at a vertex of the display panel DP or an area corresponding thereto. Two or more temperature sensors 160 may be disposed on the display panel DP.

The pads PD may be disposed in the non-display area NDA on the substrate SUB. The pads PD may be electrically connected to the sub-pixels SP through the lines. For example, the pads PD may be connected to the sub-pixels SP through the first to n-th data lines DL1 to DLn.

The pads PD may interface the display panel DP with other components of the display device 100 (e.g., refer to FIG. 1). In one or more embodiments, voltages and signals used for the operations of the components included in the display panel DP may be provided through the pads PD from the driver integrated circuit DIC (e.g., see FIG. 1). For example, the first to n-th data lines DL1 to DLn (e.g., refer to FIG. 1) may be connected to the driver integrated circuit DIC through the pads PD. For example, the first and second power voltages VDD and VSS (e.g., refer to FIG. 1) may be received from the driver integrated circuit DIC through the pads PD. In an embodiment where the gate driving circuit 120 (e.g., refer to FIG. 1) is mounted on the display panel DP, the gate control signal GCS may be transmitted from the driver integrated circuit DIC to the gate driving circuit 120 through the pads PD.

In one or more embodiments, a circuit board may be electrically connected to the pads PD by a conductive adhesive component, such as an anisotropic conductive film. The circuit board may be a flexible printed circuit board (FPCB) or a flexible film that is made of a flexible material. The driver integrated circuit DIC (e.g., refer to FIG. 1) may be mounted on the circuit board, and may be electrically connected to the pads PD.

In one or more embodiments, the display area DA may have various suitable shapes. For example, the display area DA may have a closed-loop shape including linear and/or curved sides. For example, the display area DA may have various suitable shapes, such as polygons, circles, semicircles, ellipses, and the like.

In one or more embodiments, the display panel DP may have a planar display surface. In one or more embodiments, the display panel DP may have a display surface that is at least partially rounded. In one or more embodiments, the display panel DP may be bendable, foldable, or rollable. The display panel DP and/or the substrate SUB may include rigid or flexible materials.

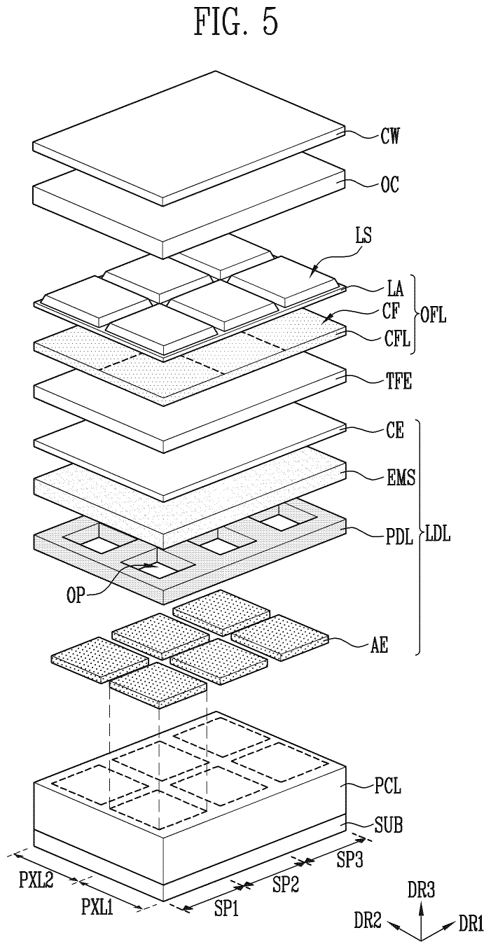

FIG. 5 is an exploded perspective view illustrating a portion of the display panel DP of FIG. 4.

In FIG. 5, for convenience of illustration, a portion of the display panel DP corresponding to pixels PXL1 and PXL2 from among the pixels PXL of FIG. 4 is schematically illustrated. The other remaining portions of the display panel DP corresponding to the other pixels may also be configured in the same or substantially the same manner.

Referring to FIGS. 4 and 5, the first and second pixels PXL1 and PXL2 may be adjacent to each other in the second direction DR2. Each of the first and second pixels PXL1 and PXL2 may include a plurality of sub-pixels. Referring to FIG. 5, each of the first and second pixels PXL1 and PXL2 may include first, second, and third sub-pixels SP1, SP2, and SP3. However, the present disclosure is not limited thereto. For example, each of the first and second pixels PXL1 and PXL2 may include four sub-pixels, or may include two sub-pixels.

In FIG. 5, a case in which the first to third sub-pixels SP1 to SP3 have rectangular shapes and the same or substantially the same size as each other when viewed in a third direction DR3 crossing or intersecting with the first and second directions DR1 and DR2 (e.g., perpendicular to the first and second directions DR1 and DR2) is illustrated. However, the present disclosure is not limited thereto. The first to third sub-pixels SP1 to SP3 may be variously modified to have various suitable shapes.

The display panel DP may include a substrate SUB, a pixel circuit layer PCL, a light-emitting-element layer LDL, a thin-film encapsulation layer TFE, an optical functional layer OFL, an overcoat layer OC, and a cover window CW.

In one or more embodiments, the substrate SUB may include a silicon wafer substrate formed through a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOl) layer, or the like.

The pixel circuit layer PCL may be disposed on the substrate SUB. The substrate SUB and/or the pixel circuit layer PCL may include insulating layers, and conductive patterns disposed between the insulating layers. The conductive patterns of the pixel circuit layer PCL may function as at least some of the circuit components, the lines, or the like. The conductive patterns may include copper, but the present disclosure is not limited thereto.

The circuit elements may include sub-pixel circuits SPC (e.g., refer to FIG. 2) of the first to third sub-pixels SP1 to SP3, respectively. The sub-pixel circuit SPC may include two or more switching elements (e.g., transistors), and one or more storage elements (e.g., capacitors). Each transistor may include a semiconductor portion including a source area, a drain area, and a channel area, and a gate electrode overlapping with the semiconductor portion (e.g., a channel area of the semiconductor portion). In an embodiment when the substrate SUB is provided using a silicon substrate, the semiconductor portions of some of the transistors may be included in the substrate SUB, and the semiconductor portions of the other transistors may be provided on the substrate SUB. The gate electrode may be included in the pixel circuit layer PCL as a conductive pattern of the pixel circuit layer PCL. The capacitor may include electrodes spaced apart from each other (e.g., facing each other). For example, each capacitor may include the electrodes that are spaced apart from each other on a plane defined in the first and second directions DR1 and DR2. For example, the capacitor may include the electrodes that are spaced apart from each other in the third direction DR3, with an insulating layer interposed therebetween.

The lines of the pixel circuit layer PCL may include signal lines connected to each of the first to third sub-pixels SP1 to SP3, for example, such as a gate line, an emission control line, and a data line. The lines may further include a line connected to the first power voltage node VDDN (e.g., see FIG. 2). The lines may further include a line connected to the second power voltage node VSSN (e.g., see FIG. 2).

The light-emitting-element layer LDL may include anode electrodes AE, a pixel defining layer PDL, an emission structure EMS, and a cathode electrode CE.

The anode electrodes AE may be disposed on the pixel circuit layer PCL. The anode electrodes AE may be connected to (e.g., brought into contact with) circuit elements of the pixel circuit layer PCL. The anode electrodes AE may include an opaque conductive material capable of reflecting light. However, the present disclosure is not limited thereto. In one or more embodiments, each of the anode electrodes AE may include at least one of various suitable transparent conductive materials, such as indium tin oxide (ITO), indium zinc oxide (IZO), zinc oxide (ZnO), indium gallium zinc oxide (IGZO), and/or indium tin zinc oxide (ITZO). However, the material of the anode electrode AE is not limited to the foregoing examples. For example, the anode electrode AE may include titanium nitride.

The pixel defining layer PDL may be disposed on the anode electrodes AE. The pixel defining layer PDL may include openings OP that expose at least a portion of each of the anode electrodes AE. The openings OP in the pixel defining layer PDL may correspond to the emission areas of the first to third sub-pixels SP1 to SP3, respectively.

In one or more embodiments, the pixel defining layer PDL may include an inorganic material. In the present embodiment, the pixel defining layer PDL may include an inorganic layer (e.g., a plurality of stacked inorganic layers). For example, the pixel defining layer PDL may include silicon oxide (SiOₓ) and/or silicon nitride (SiNₓ). In other embodiments, the pixel defining layer PDL may include an organic layer including an organic material. However, the material constituting the pixel defining layer PDL in accordance with embodiments of the present disclosure is not limited to the aforementioned examples.

The emission structure EMS may be disposed on the anode electrodes AE exposed through the openings OP in the pixel defining layer PDL. The emission structure EMS may include one or more functional layers. For example, the emission structure EMS may include one or more functional layers, such as a light generation layer (e.g., an emission layer) to generate light, an electron transport layer to transport electrons, and a hole transport layer to transport holes.

In one or more embodiments, the openings OP in the pixel defining layer PDL may be filled with the emission structure EMS. In one or more embodiments, the emission structure EMS may be disposed over the overall surface of the pixel defining layer PDL. For example, the emission structure EMS may extend over the first to third sub-pixels SP1 to SP3. In the present embodiment, at least some of the functional layers in the emission structure EMS may be cut or bent at (e.g., in or on) boundaries between the first to third sub-pixels SP1 to SP3. However, the present disclosure is not limited thereto. For example, portions of the emission structure EMS corresponding to the first to third sub-pixels SP1 to SP3 may be spaced apart or separated from each other, and each of the portions may be disposed in a corresponding opening OP in the pixel defining layer PDL.

The cathode electrode CE may be disposed on the emission structure EMS. The cathode electrode CE may be provided over the first to third sub-pixels SP1 to SP3. The cathode electrode CE may be provided as a common electrode that is connected in common to the first to third sub-pixels SP1 to SP3.

The cathode electrode CE may have light transmissive properties. For example, the cathode electrode CE may be a thin-film metal layer having a suitable thickness for allowing light emitted from the emission structure EMS to pass therethrough. The cathode electrode CE may be formed of a metal material having a relatively small thickness, or may be formed of a conductive material (e.g., a transparent material) having light transmissive properties. In one or more embodiments, the cathode electrode CE may include at least one of various suitable transparent conductive materials including indium tin oxide, indium zinc oxide, indium tin zinc oxide, aluminum zinc oxide, gallium zinc oxide, zinc tin oxide, or gallium tin oxide. However, the material constituting the cathode electrode CE in accordance with one or more embodiments of the present disclosure is not limited to the aforementioned examples. The cathode electrode CE may function as a half mirror to partially transmit and partially reflect light emitted from the emission structure EMS.

Any one anode electrode AE, a portion of the emission structure EMS that overlaps with the any one anode electrode AE, and a portion of the cathode electrode CE that overlaps with the portion of the emission structure EMS may be understood as constituting one light emitting element LD (e.g., refer to FIG. 2). Each of the light emitting elements LD of the first to third sub-pixels SP1 to SP3 may include one anode electrode AE, a portion of the emission structure EMS that overlaps with the one anode electrode AE, and a portion of the cathode electrode CE that overlaps with the portion of the emission structure EMS. In each of the first to third sub-pixels SP1 to SP3, holes injected from the anode electrode AE and electrons injected from the cathode electrode CE are transported into the emission structure EMS, and thus, forming excitons. When the excitons make a transition from an excited state to a ground state, light may be generated. The luminance of light may be determined based on the amount of current flowing through the emission structure EMS. Depending on the configuration of the emission structure EMS, the wavelength range of light to be generated from the emission structure EMS may be determined.

The thin-film encapsulation layer TFE may be disposed on the cathode electrode CE. The thin-film encapsulation layer TFE may cover the light-emitting-element layer LDL and/or the pixel circuit layer PCL. The thin-film encapsulation layer TFE may prevent or substantially prevent oxygen, water, and/or the like from penetrating into the light-emitting-element layer LDL. In one or more embodiments, the thin-film encapsulation layer TFE may include a structure formed by alternately stacking one or more inorganic layers and one or more organic layers on one another. For example, the inorganic layer may include silicon nitride, silicon oxide, silicon oxynitride (SiOₓN_{y}), or the like. For example, the organic layer may include an organic insulating material, such as acrylic resin, epoxy resin, phenol resin, polyamide resin, polyimide resin, unsaturated polyester resin, polyphenylenether resin, polyphenylenesulfide resin, or benzocyclobutene (BCB). However, the materials of the organic layer and the inorganic layer of the thin-film encapsulation layer TFE are limited to the aforementioned examples.

The thin-film encapsulation layer TFE may further include a thin film, such as aluminum oxide (AlOₓ), to enhance the encapsulation efficiency of the thin-film encapsulation layer TFE. The thin film including aluminum oxide may be positioned on an upper surface of the thin-film encapsulation layer TFE that faces the optical functional layer OFL, and/or under a lower surface of the thin-film encapsulation layer TFE that faces the light-emitting-element layer LDL. The thin film including aluminum oxide may be formed by an atomic layer deposition (ALD) method. However, the present disclosure is not limited thereto. The thin-film encapsulation layer TFE may further include a thin film formed of at least one of various suitable materials for enhancing an encapsulation efficiency.

The optical functional layer OFL may be disposed on the thin-film encapsulation layer TFE. The optical functional layer OFL may include a color filter layer CFL and a lens array LA. In one or more embodiments, the optical functional layer OFL may be attached to the encapsulation layer TFE through an adhesive layer. For example, the optical functional layer OFL may be fabricated through a separate process, and attached to the encapsulation layer TFE by the adhesive layer. The adhesive layer may further perform a function of protecting the underlying layers including the encapsulation layer TFE.

The color filter layer CFL may be disposed between the thin-film encapsulation layer TFE and the lens array LA. The color filter layer CFL may filter light emitted from the emission structure EMS to selectively output light in a wavelength band corresponding to each of the sub-pixels. The color filter layer CFL may include color filters CF that correspond to the first to third sub-pixels SP1 to SP3, respectively. Each of the color filters CF allows light in a desired wavelength band corresponding to the corresponding sub-pixel to pass therethrough. For example, the color filter corresponding to the first sub-pixel SP1 allows light in a first wavelength band (e.g., a red color) to pass therethrough. The color filter corresponding to the second sub-pixel SP2 allows light in a second wavelength band (e.g., a green color) to pass therethrough. The color filter corresponding to the third sub-pixel SP3 allows light in a third wavelength band (e.g., a blue color) to pass therethrough. The red color light may be light having a wavelength ranging from approximately 630 nm (nanometer) to approximately 750 nm. The green color light may be light having a wavelength ranging from approximately 495 nm to approximately 570 nm. The blue color light may be light having a wavelength ranging from approximately 450 nm to approximately 495 nm.

Depending on the color of the light emitted from the emission structure EMS in each sub-pixel, at least some of the color filters CF may be omitted. In an embodiment, the color filter layer CFL may be omitted. In one or more embodiments, the color filters CF may overlap with (e.g., partially overlap with) each other in boundary areas between the first to third sub-pixels SP1 to SP3. In other embodiments, the color filters CF may be spaced apart from each other in the boundary areas between the first to third sub-pixels SP1 to SP3, and a black matrix may be provided between the color filters CF.

The lens array LA may be disposed on the color filter layer CFL. The lens array LA may include lenses LS that correspond to the first to third sub-pixels SP1 to SP3, respectively. Each of the lenses LS may output and direct light emitted from the emission structure EMS along a desired path (e.g., an intended path), and thus, light output efficiency may be enhanced. The lens array LA may have a relatively high refractive index. In one or more embodiments, the lenses LS may include an organic material. In one or more embodiments, the lenses LS may include an acrylate material. However, the material constituting the lenses LS is not limited to the foregoing examples.

In one or more embodiments, compared to the positions of the openings OP in the pixel defining layer PDL, at least some of the color filters CF and/or at least some of the lenses LS may be shifted. For example, at least some of the color filters CF of the color filter layer CFL and at least some of the lenses LS of the lens array LA may be shifted from vertical lines of the corresponding openings OP (e.g., the centers of the openings OP) in any one direction parallel to or substantially parallel to a plane defined by the first and second directions DR1 and DR2.

In more detail, in a central area of the display area DA, the center of the color filter CF and the center of the lens LS may be aligned or overlapped with the center of the corresponding opening OP in the pixel defining layer PDL. For example, in the central area of the display area DA, the opening OP in the pixel defining layer PDL may completely overlap with the corresponding color filter CF of the color filter layer CFL and the corresponding lens LS of the lens array LA. In an area of the display area DA that is adjacent to the non-display area NDA, the center of the color filter CF and the center of the lens LS may be shifted in a plane direction from the center of the corresponding opening OP of the pixel defining layer PDL when viewed in the third direction DR3 (e.g., in a plan view). For example, in the area adjacent to the non-display area NDA in the display area DA, each opening OP of the pixel defining layer PDL may partially overlap with the corresponding color filter CF of the color filter layer CFL and the corresponding lens LS of the lens array LA. Accordingly, light emitted from the emission structure EMS in the central portion of the display area DA may be efficiently output in the normal direction of the display surface. Light emitted from the emission structure EMS around the perimeter of the display area DA may be efficiently output in a direction inclined at an angle (e.g., a certain or predetermined angle) with respect to the normal direction of the display surface.

The overcoat layer OC may be disposed on the lens array LA. The overcoat layer OC may cover the optical functional layer OFL, the thin-film encapsulation layer TFE, the emission structure EMS, and/or the pixel circuit layer PCL. The overcoat layer OC may include various suitable materials for protecting the underlying layers from foreign substances, such as dust, water, and/or the like.

The cover window CW may be disposed on the overcoat layer OC. The cover window CW may protect the underlying layers. In one or more embodiments, the cover window CW may include light-transmitting (e.g., transparent) glass, a metal, or the like. However, the present disclosure is not limited thereto.

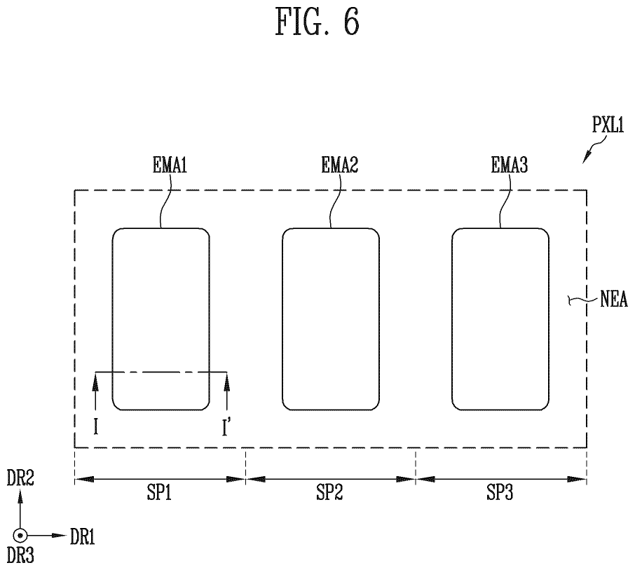

FIG. 6 is a plan view illustrating an embodiment of any one pixel of FIG. 5.

In FIG. 6, for convenience of illustration, the first pixel PXL1 of the first and second pixels PXL1 and PXL2 (e.g., see FIG. 5) are schematically depicted. The other pixels may be configured in the same or substantially the same manner as that of the first pixel PXL1. The first pixel PXL1 may include first to third sub-pixels SP1 to SP3 that are arranged along the first direction DR1.

The first sub-pixel SP1 may include a first emission area EMA1, and a non-emission area NEA formed around (e.g., to surround around a periphery of) the first emission area EMA1. The second sub-pixel SP2 may include a second emission area EMA2, and a non-emission area NEA formed around (e.g., to surround around a periphery of) the second emission area EMA2. The third sub-pixel SP3 may include a third emission area EMA3, and a non-emission area NEA formed around (e.g., to surround around a periphery of) the third emission area EMA3.

The first emission area EMA1 may be an area where light is emitted from a portion of the emission structure EMS (e.g., refer to FIG. 5) that corresponds to the first sub-pixel SP1. The second emission area EMA2 may be an area where light is emitted from a portion of the emission structure EMS that corresponds to the second sub-pixel SP2. The third emission area EMA3 may be an area where light is emitted from a portion of the emission structure EMS that corresponds to the third sub-pixel SP3. As described above with reference to FIG. 5, each emission area may be understood as a corresponding opening OP of the pixel defining layer PDL for each of the first to third sub-pixels SP1 to SP3.

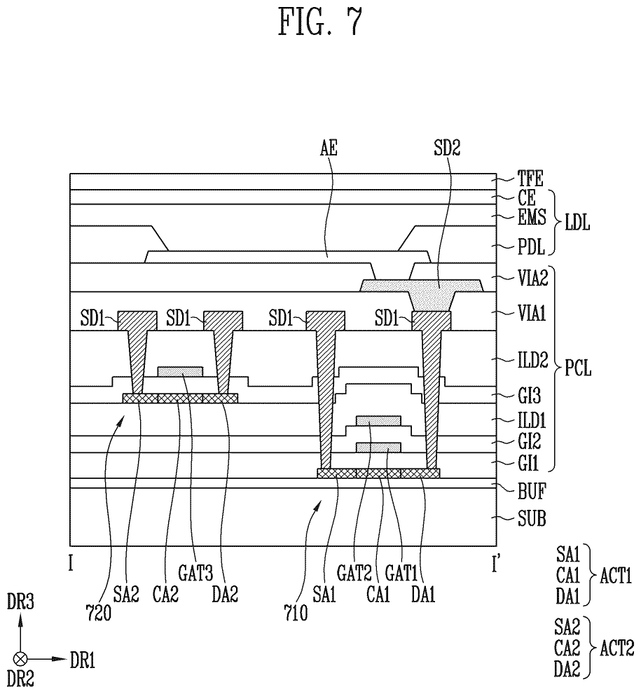

FIG. 7 illustrates a cross-sectional view taken along the line I-I′ of FIG. 6.

Referring to FIG. 7, the display panel DP includes the substrate SUB, and the pixel circuit layer PCL disposed on the substrate SUB.

The substrate SUB may include a silicon wafer substrate formed through a semiconductor process. For example, the substrate SUB may include silicon, germanium, and/or silicon-germanium.

A buffer layer BUF may be disposed on the substrate SUB. The buffer layer BUF may be formed by injecting oxygen ions into the silicon substrate SUB, for example. The buffer layer BUF may include an inorganic insulating material, such as silicon oxide (e.g., SiO₂), silicon oxynitride, or silicon nitride. The buffer layer BF may have a single-layer structure or a multilayered structure including one or more of the foregoing materials.

A first active pattern ACT1 may be disposed on the buffer layer BUF. The first active pattern ACT1 may be provided as, for example, a semiconductor on insulator (SeOI) layer. The first active pattern ACT1 may include a first source area SA1, a first drain area DA1, and a first channel area CA1. The first channel area CA1 may be located between the first source area SA1 and the first drain area DA1. The first active pattern ACT1 may be implemented as a P-type semiconductor layer. For example, the first active pattern ACT1 may be formed by doping the substrate SUB including silicon (Si) (e.g., single-crystalline silicon (Si)) with P-type impurities (e.g., phosphorus (P), arsenic (As), and/or the like). In an embodiment, the first source area SA1 and the first drain area DA1 may be disposed in the substrate SUB. Formed through an ion injection process, a well may be disposed in the substrate SUB. The source area SA1 and the drain area DA1 may be disposed to be spaced apart from each other in the well. In the well, an area between the source area SA1 and the drain area DA1 may be defined as the first channel area CA1.

A first gate insulating layer GI1 may be disposed on the first active pattern ACT1. The first gate insulating layer GI1 may be formed of an inorganic insulating layer including an inorganic material. The first gate insulating layer GI1 may include an inorganic insulating material, such as silicon oxide (SiO₂), silicon nitride (SiNₓ) (where x is a positive number), silicon oxynitride (SiON), aluminum oxide (Al₂O₃), titanium oxide (TiO₂), tantalum oxide (Ta₂O₅), hafnium oxide (HfO₂), and/or zinc oxide (ZnO₂).

A first gate electrode GAT1 may be disposed on the first gate insulating layer GI1. The first gate electrode GAT1 may overlap with the first channel area CA1 of the first active pattern ACT11. The first gate electrode GAT1 may include a metal. For example, the first gate electrode GAT1 may be made of at least one of various suitable metals, such as gold (Au), silver (Ag), aluminum (AI), molybdenum (Mo), chrome (Cr), titanium (Ti), nickel (Ni), neodymium (Nd), copper (Cu), tungsten (W), or a suitable alloy of the metals. Furthermore, the first gate electrode GAT1 may have a single layer structure, or a multilayered structure formed by stacking layers made of two or more materials of the metals and/or the alloys. The first gate electrode GAT1 may constitute the gate electrode of the first transistor TR1 (e.g., refer to FIG. 3). The first gate electrode GAT1 may constitute one side electrode of the storage capacitor Cst (e.g., refer to FIG. 3).

A second gate insulating layer GI2 may be disposed on the first gate electrode GAT1. The second gate insulating layer GI2 may be formed of an inorganic insulating layer including an inorganic material. The second gate insulating layer GI2 may include an inorganic insulating material, such as silicon oxide (SiO₂), silicon nitride (SiNₓ) (where x is a positive number), silicon oxynitride (SiON), aluminum oxide (Al₂O₃), titanium oxide (TiO₂), tantalum oxide (Ta₂O₅), hafnium oxide (HfO₂), and/or zinc oxide (ZnO₂).

A second gate electrode GAT2 may be disposed on the second gate insulating layer GI2. The second gate electrode GAT2 may overlap with at least a portion of the first gate electrode GAT1. The second gate electrode GAT2 may constitute one side electrode of the storage capacitor Cst (e.g., refer to FIG. 3). Referring to FIG. 3, the second gate electrode GAT2 may constitute a portion of the second node N2. The second gate electrode GAT2 may include a metal. For example, the second gate electrode GAT2 may be made of at least one of various suitable metals, such as gold (Au), silver (Ag), aluminum (AI), molybdenum (Mo), chrome (Cr), titanium (Ti), nickel (Ni), neodymium (Nd), copper (Cu), tungsten (W), or a suitable alloy of the metals. Furthermore, the second gate electrode GAT2 may have a single layer structure, or a multilayered structure formed by stacking layers made of two or more materials of the metals and/or the alloys.

A first interlayer insulating layer ILD1 may be disposed on the second gate electrode GAT2. The first interlayer insulating layer ILD1 may be an inorganic insulating layer including an inorganic material. Polysiloxane, silicon nitride, silicon oxide, silicon oxynitride, or the like may be used as the inorganic material. However, the present disclosure is not limited thereto.

A second active pattern ACT2 may be disposed on the first interlayer insulating layer ILD1. In an embodiment, the second active pattern ACT2 may be formed of an oxide semiconductor. The second active pattern ACT2 may include a metal oxide semiconductor. For example, the second active pattern ACT2 may include indium gallium zinc oxide (IGZO), but the present disclosure is not limited thereto. The second active pattern ACT2 may be doped with an N-type impurity. For example, phosphorus (P), arsenic (As), antimony (Sb), and/or the like may be used as the N-type impurity. For example, the second active pattern ACT2 may be formed by depositing a metal oxide using a sputtering method, and etching (e.g., dry etching) the metal oxide. However, the present disclosure is not limited thereto.

The second active pattern ACT2 may include a second source area SA2, a second drain area DA2, and a second channel area CA2. The second channel area CA2 may be located between the second source area SA2 and the second drain area DA2. The second active pattern ACT2 may be implemented as an N-type semiconductor layer.

A third gate insulating layer GI3 may be disposed on the second active pattern ACT2. The third gate insulating layer GI3 may be formed of an inorganic insulating layer including an inorganic material. The third gate insulating layer GI3 may include an inorganic insulating material, such as silicon oxide (SiO₂), silicon nitride (SiNₓ) (where x is a positive number), silicon oxynitride (SiON), aluminum oxide (Al₂O₃), titanium oxide (TiO₂), tantalum oxide (Ta₂O₅), hafnium oxide (HfO₂), and/or zinc oxide (ZnO₂).

A third gate electrode GAT3 may be disposed on the third gate insulating layer GI3. The third gate electrode GAT3 may overlap with the second channel area CA2 of the second active pattern ACT2. The third gate electrode GAT3 may constitute the gate electrode of the third transistor TR3 (e.g., refer to FIG. 3) or the fourth transistor TR4. The third gate electrode GAT3 may include a metal. For example, the third gate electrode GAT3 may be made of at least one of various suitable metals, such as gold (Au), silver (Ag), aluminum (AI), molybdenum (Mo), chrome (Cr), titanium (Ti), nickel (Ni), neodymium (Nd), copper (Cu), tungsten (W), or a suitable alloy of the metals. Furthermore, the third gate electrode GAT3 may have a single-layer structure, or a multilayered structure formed by stacking layers made of two or more materials of the metals and/or the alloys.

A second interlayer insulating layer ILD2 may be provided on the third gate electrode GAT3. The second interlayer insulating layer ILD2 may be an inorganic insulating layer including an inorganic material. Polysiloxane, silicon nitride, silicon oxide, silicon oxynitride, or the like may be used as the inorganic material. However, the present disclosure is not limited thereto.

A first source/drain electrode SD1 may be provided on the second interlayer insulating layer ILD2. The first source/drain electrode SD1 may be connected to a corresponding first active pattern ACT1 or second active pattern ACT2. For example, the first source/drain electrode SD1 may be connected to the first source area SA1 of the first active pattern ACT1, or may be connected to the first drain area DA1. For example, the first source/drain electrode SD1 may be connected to the second source area SA2 of the second active pattern ACT2, or may be connected to the second drain area DA2.

The first source/drain electrode SD1 may include a metal. The first source/drain electrode SD1 may include a suitable material having excellent conductivity. For example, the first source/drain electrode SD1 may include a conductive material including molybdenum (Mo), aluminum (AI), copper (Cu), titanium (Ti), or the like. The first source/drain electrode SD1 may have a single-layer structure or multilayered structure including one or more of the foregoing materials. For example, the first source/drain electrode SD1 may have a multilayered structure of Ti/Al/Ti.

Referring to FIG. 7, the first active pattern ACT1, the first gate electrode GAT1, and the first source/drain electrode SD1 may constitute a P-type transistor 710. The P-type transistor 710 may include a single-crystalline silicon semiconductor. Referring to FIG. 3, each of the first, second, and fifth to seventh transistors TR1, TR2, and TR5 to TR7 may be implemented as a P-type transistor 710.

Referring to FIG. 7, the second active pattern ACT2, the third gate electrode GAT3, and the first source/drain electrode SD1 may constitute an N-type transistor 720. The N-type transistor 720 may include a metal oxide semiconductor. Referring further to FIG. 3, each of the third and fourth transistors TR3 and TR4 may be implemented as an N-type transistor 720.

A first via layer VIA1 may be provided on the first source/drain electrode SD1. For example, the first via layer VIA1 may be formed of an organic insulating layer including an organic material. The first via layer VIA1 may include an organic insulating material, such as, for example, a general-purpose polymer such as polymethylmethacrylate or polystyrene, a polymer derivative including a phenolic group, an acrylic polymer, an imide-based polymer, an aryl ether-based polymer, an amide-based polymer, fluorinate polymer, a p-xylene-based polymer, a vinyl alcohol-based polymer, and/or a suitable blend thereof. The first via layer VIA1 may function to planarize or substantially planarize an area on the first source/drain electrode SD1.

A second source/drain electrode SD2 may be provided on the first via layer VIA1. The second source/drain electrode SD2 may be connected to the corresponding first source/drain electrode SD1. The second source/drain electrode SD2 may connect first source/drain electrodes SD1 positioned to be spaced apart from each other, or may connect the corresponding first source/drain electrode SD1 to an electrode in an upper layer (e.g., an anode electrode or the like).

A second via layer VIA2 may be provided on the second source/drain electrode SD2. For example, the second via layer VIA2 may be formed of an organic insulating layer including an organic material. The second via layer VIA2 may include an organic insulating material, such as, for example, a general-purpose polymer such as polymethylmethacrylate or polystyrene, a polymer derivative including a phenolic group, an acrylic polymer, an imide-based polymer, an aryl ether-based polymer, an amide-based polymer, fluorinate polymer, a p-xylene-based polymer, a vinyl alcohol-based polymer, and/or a suitable blend thereof. The second via layer VIA2 may function to planarize or substantially planarize an area on the second source/drain electrode SD2.

The light-emitting-element layer LDL may be disposed on the second via layer VIA2. The light-emitting-element layer LDL may include an anode electrode AE, a pixel defining layer PDL, an emission structure EMS, a cathode electrode CE, and the like

The anode electrode AE may be disposed on the second via layer VIA2. The anode electrode AE may be connected to the second source/drain electrode SD2 through a via hole passing through (e.g., penetrating) the second via layer VIA2. In one or more embodiments, the anode electrode AE may include a metal layer made of silver (Ag), magnesium (Mg), aluminum (AI), platinum (Pt), palladium (Pd), gold (Au), nickel (Ni), neodymium (Nd), iridium (Ir), chrome (Cr), or a suitable alloy thereof, and/or indium tin oxide (ITO), indium zinc oxide (IZO), zinc oxide (ZnO), indium tin zinc oxide (ITZO), or the like. However, the material of the anode electrode AE is not limited to the foregoing examples. For example, the anode electrode AE may include titanium nitride.

The pixel defining layer PDL may be disposed on the anode electrode AE. The pixel defining layer PDL may include an opening that exposes at least a portion of the anode electrode AE. The opening in the pixel defining layer PDL may define an emission area through which light is emitted from a corresponding one of the first to third sub-pixels SP1 to SP3 (e.g., refer to FIG. 6). The pixel defining layer PDL may be disposed in the non-emission area NEA (e.g., see FIG. 6). The pixel defining layer PDL may define the first to third emission areas EMA1 to EMA3 (e.g., see FIG. 6). The pixel defining layer PDL may include a light absorbing material or may be coated with a light absorbent, so that the pixel defining layer PDL may function to absorb light introduced from the outside. For example, the pixel defining layer PDL may include a carbon-based black pigment. However, the present disclosure is not limited thereto. The pixel defining layer PDL may include an opaque metal having high light absorptivity, such as chrome (Cr), molybdenum (Mo), an alloy (MoTi) of molybdenum and titanium, tungsten (W), vanadium (V), niobium (Nb), tantalum (Ta), manganese (Mn), cobalt (Co), or nickel (Ni).

In one or more embodiments, the pixel defining layer PDL may include a plurality of inorganic insulating layers. Each of the inorganic insulating layers may include at least one of silicon oxide (SiOx) and/or silicon nitride (SiNₓ). For example, the pixel defining layer PDL may include first to third inorganic insulating layers that are successively stacked on one another. The first to third inorganic insulating layers may respectively include silicon nitride, silicon oxide, and silicon nitride. However, the present disclosure is not limited thereto. The first to third insulating layers may have a stepped shape in an area adjacent to each of the openings.

In an embodiment, a separator may be provided (e.g., disposed) in a boundary area between neighboring sub-pixels. In other words, the separator may be provided in each of the boundary areas between the sub-pixels SP (e.g., see FIG. 1). The separator may form a discontinuity in the emission structure EMS in the boundary area. For example, the emission structure EMS may be cut or bent in the boundary area by the separator.

The emission structure EMS may be disposed on the anode electrodes AE exposed through the openings in the pixel defining layer PDL. The emission structure EMS may fill the openings of the pixel defining layer PDL, and may be disposed over the overall areas of the first to third sub-pixels SP1 to SP3 (e.g., refer to FIG. 6). As described above, at least a portion of the emission structure EMS may be partially cut or bent in the boundary area BDA by the separator. As such, a magnitude of a current (e.g., a leakage current) leaking from each of the first to third sub-pixels SP1 to SP3 to a sub-pixel neighboring (e.g., adjacent) thereto through the layers included in the emission structure EMS during the operation of the display panel may be reduced or removed.

The cathode electrode CE may be disposed on the emission structure EMS. The cathode electrode CE may be provided (e.g., disposed) in common to the first to third sub-pixels SP1 to SP3 (e.g., refer to FIG. 6). The cathode electrode CE may function as a half mirror, partially transmitting and partially reflecting light emitted from the emission structure EMS. The cathode electrode CE may be formed of a metal layer formed of a suitable material, such as silver (Ag), magnesium (Mg), aluminum (AI), platinum (Pt), palladium (Pd), gold (Au), nickel (Ni), neodymium (Nd), iridium (Ir), chrome (Cr), or a suitable alloy thereof, and/or a transparent conductive layer formed of a suitable material, such as ITO, IZO, ZnO, or ITZO. In an embodiment, the cathode electrode CE may have a multilayered structure having two or more layers including a thin metal layer. For example, the cathode electrode CE may have a triple-layered structure including ITO/Ag/ITO.

The thin-film encapsulation layer TFE may be disposed on the cathode electrode CE. The thin-film encapsulation layer TFE may prevent or substantially prevent oxygen, water, and/or the like from penetrating into the light-emitting-element layer LDL. The thin-film encapsulation layer TFE may have a single-layer structure, or may have a multilayered structure. In an embodiment, the thin-film encapsulation layer TFE may have a stacked structure in which an inorganic material, an organic material, and an inorganic material are deposited in the order listed. An uppermost layer of the thin-film encapsulation layer TFE may include an inorganic material.

The buffer layer BUF and the first active pattern ACT1 may be directly formed on the substrate SUB1. The first gate insulating layer GI1, the second gate insulating layer GI2, the first interlayer insulating layer ILD1, the third gate insulating layer GI3, the second interlayer insulating layer ILD2, the first vial layer VIA1, and the second via layer VIA2 may constitute the pixel circuit layer PCL. The pixel circuit layer PCL may be formed on the substrate SUB.

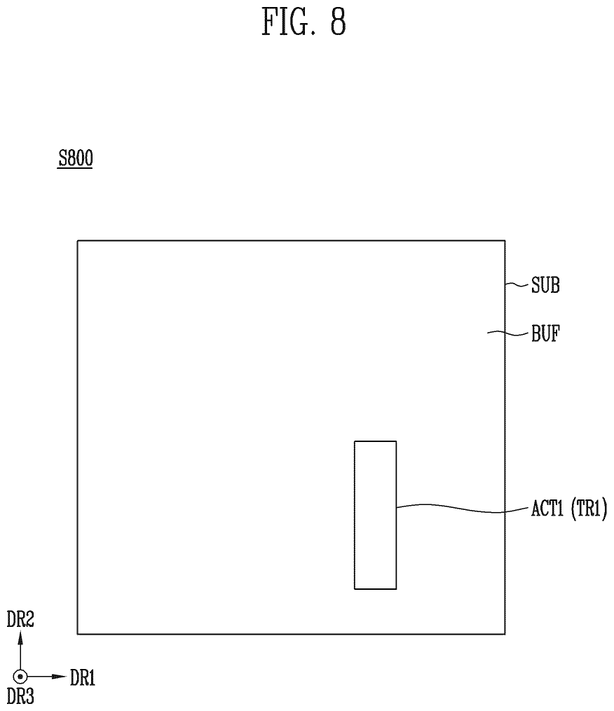

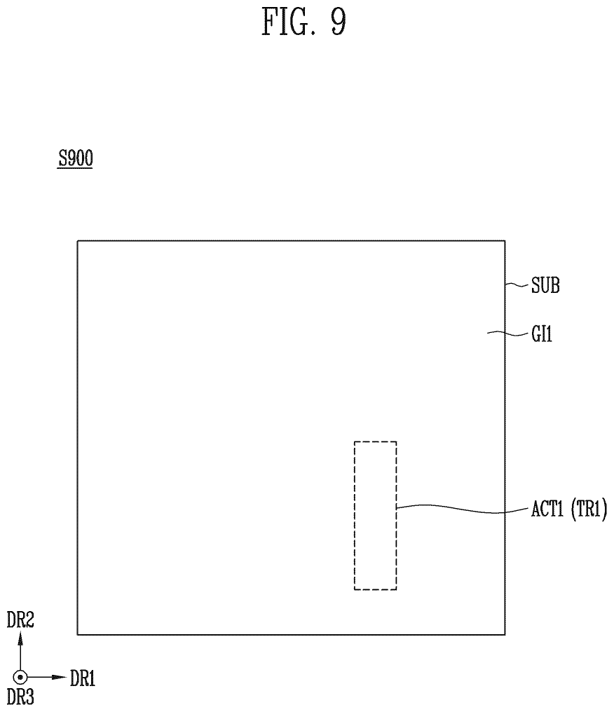

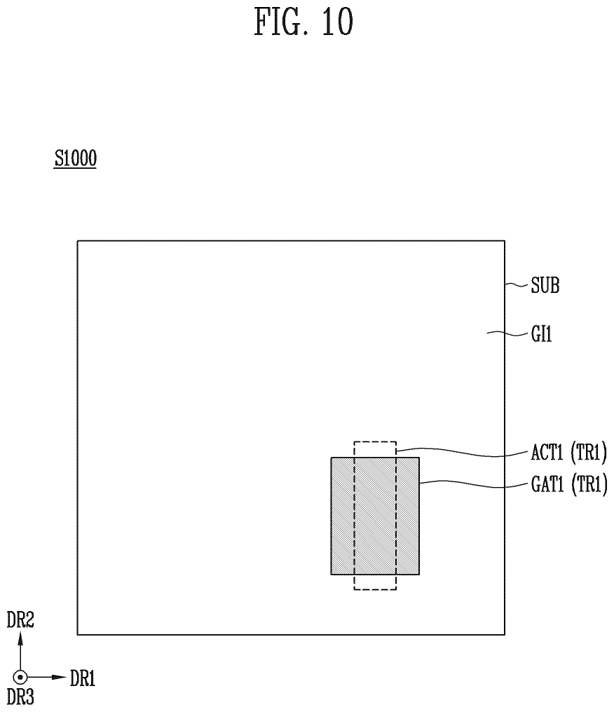

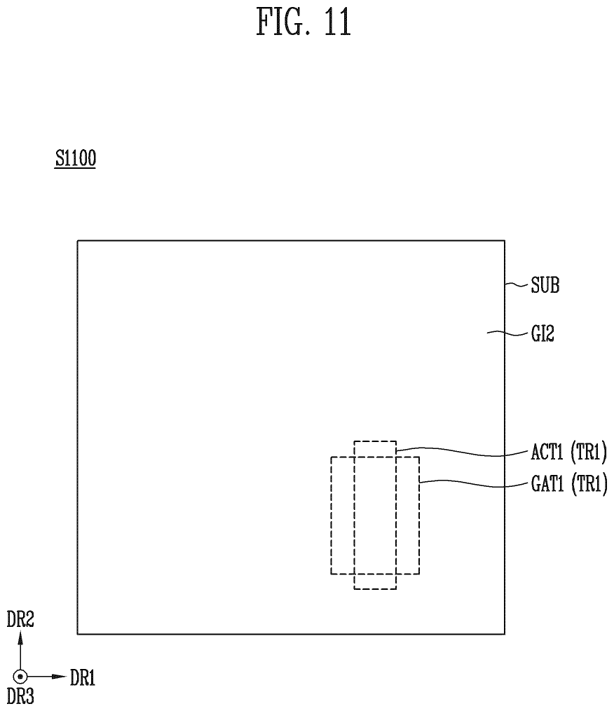

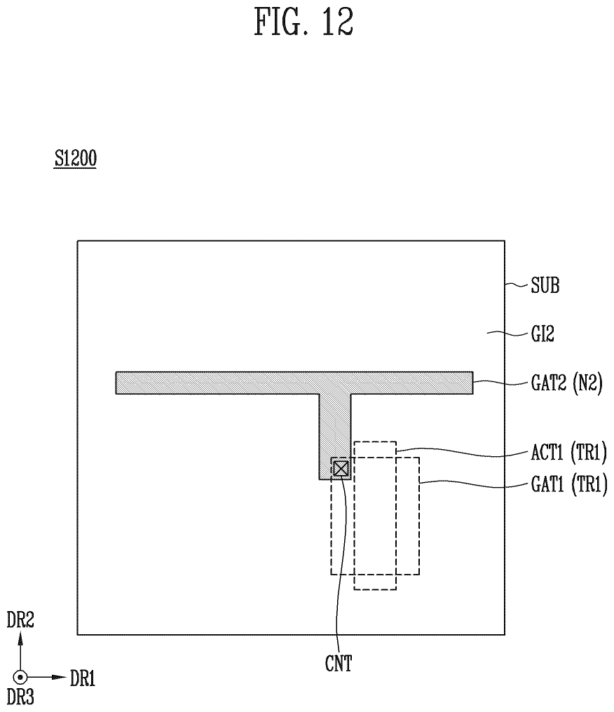

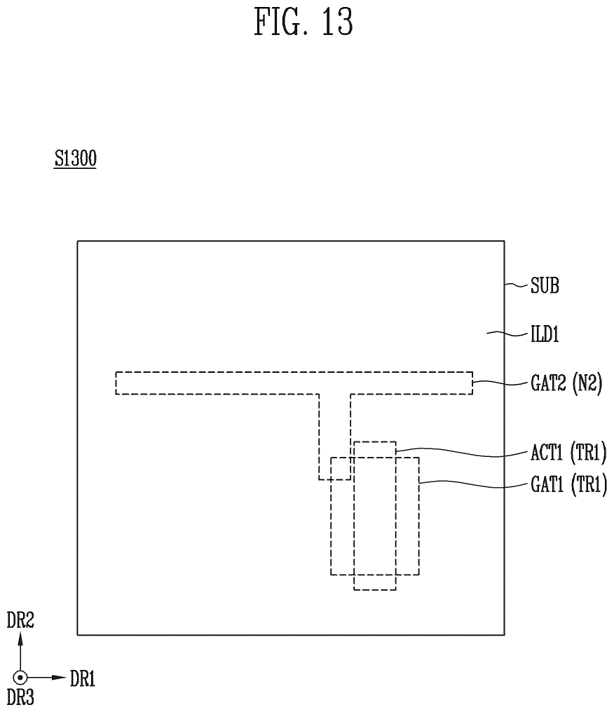

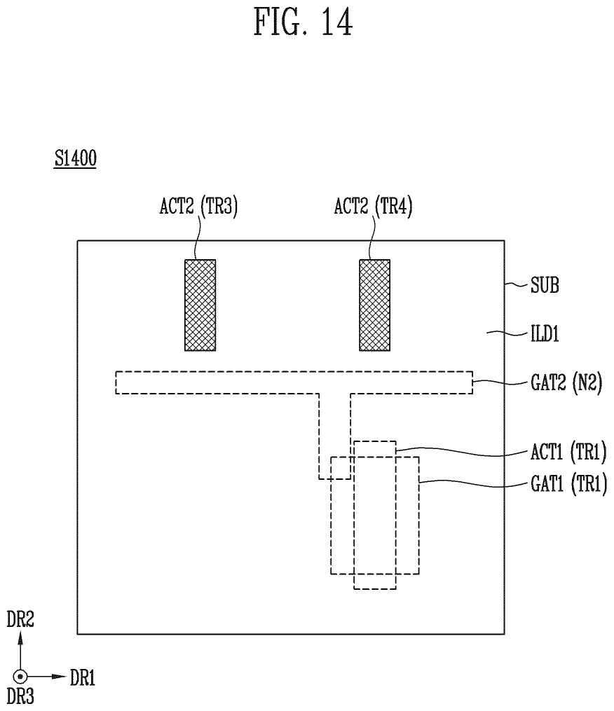

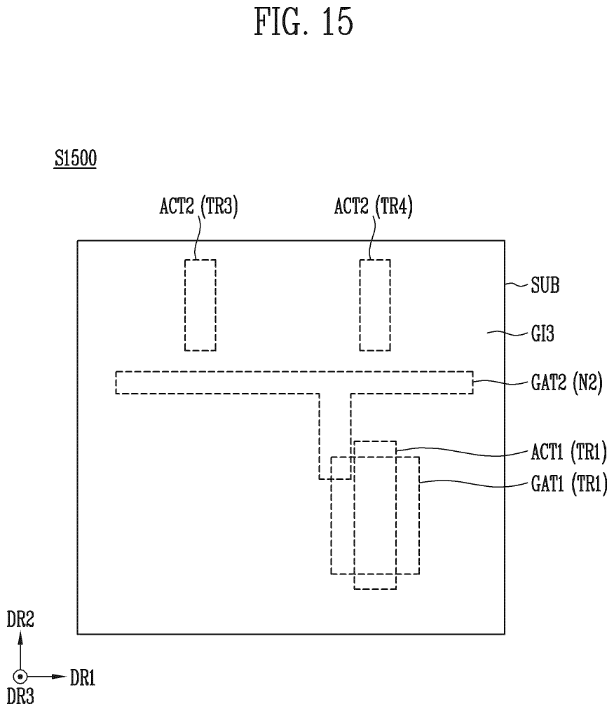

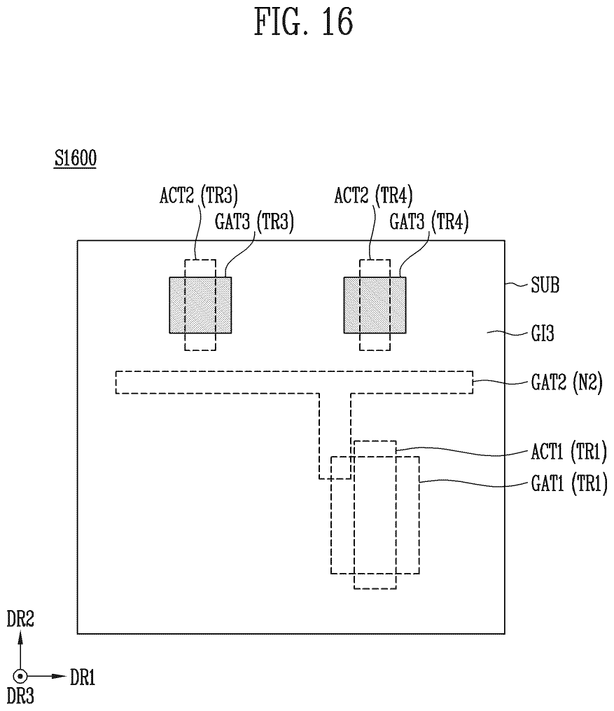

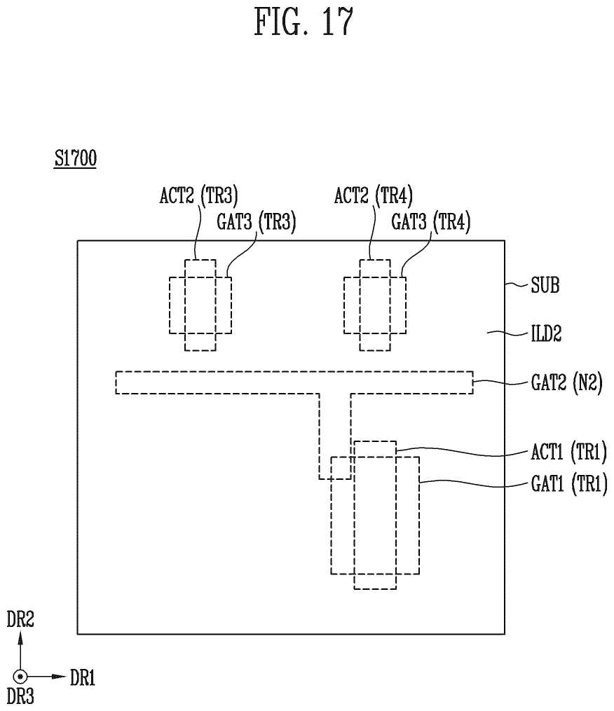

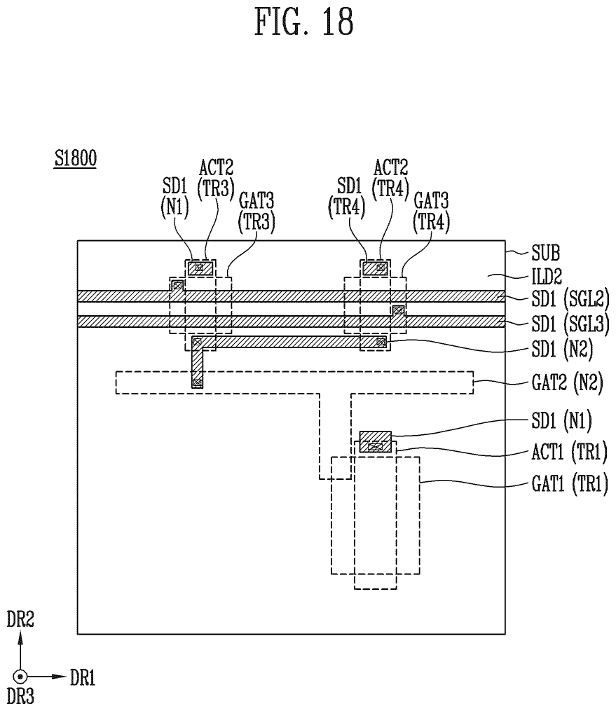

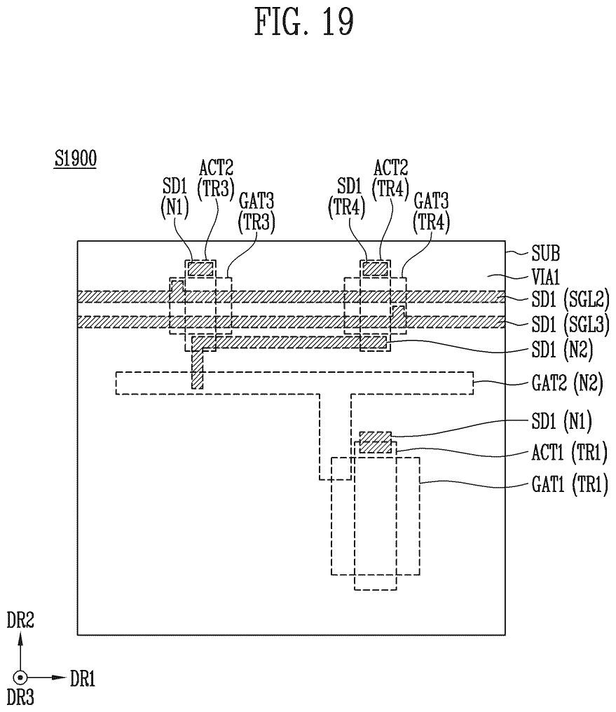

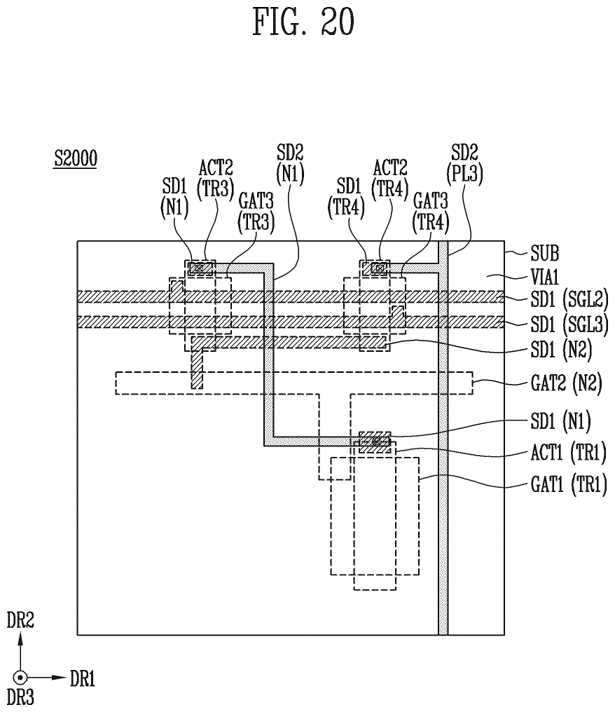

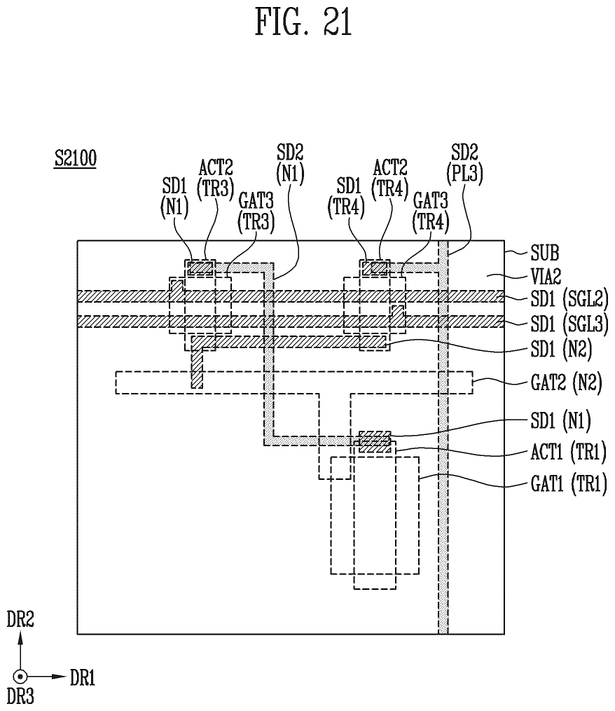

FIGS. 8 through 21 illustrate a method of fabricating the display panel in accordance with one or more embodiments of the present disclosure.

For convenience of illustration, the method of fabricating the display panel in accordance with one or more embodiments of the present disclosure will be described in more detail focusing on a process of forming the first transistor TR1, the third transistor TR3, and the fourth transistor TR4 (e.g., see FIG. 3).

1 For example, during a process of forming the first transistor TR1, the second and fifth to seventh transistors TR2 and TR5 to TR7 (e.g., see FIG. 3) may be further formed, but are not illustrated for convenience. Hereinafter, a process of forming the transistors and the lines will be described in more detail with reference to FIG. 3.

The method of fabricating the display panel in accordance with one or more embodiments of the present disclosure may include forming the first active pattern ACT1 (S800).

When forming the first active pattern ACT1 (S800), the first active pattern ACT1 may be formed on the buffer layer BUF on the substrate SUB. The first active pattern ACT1 may be provided as an SeOl layer. The buffer layer BUF may be formed by injecting oxygen ions into the substrate SUB. The first active pattern ACT1 may be formed of a P-type semiconductor layer. At the forming of the first active pattern ACT1, a process of doping P-type impurities may be performed. Aluminum (AI), gallium (Ga), indium (In), and/or the like may be used as the P-type impurities. The first active pattern ACT1 may be a semiconductor layer of the first transistor TR1 (e.g., see FIG. 3).

The method of fabricating the display panel in accordance with one or more embodiments of the present disclosure may include forming the first gate insulating layer GI1 (S900).

The first gate insulating layer GI1 may cover the entireties of the first active pattern ACT1 and the buffer layer BUF.

The method of fabricating the display panel in accordance with one or more embodiments of the present disclosure may include forming the first gate electrode GAT1 (S1000).

The first gate electrode GAT1 may be positioned to overlap with at least a portion of the first active pattern ACT1 (e.g., in the third direction DR3). The first gate electrode GAT1 may form the gate electrode of the first transistor TR1.

1 The method of fabricating the display panel in accordance with one or more embodiments of the present disclosure may include forming the second gate insulating layer GI2 (S1100).

The second gate insulating layer GI2 may cover the entireties of the first gate electrode GAT1 and the first gate insulating layer GI1.

The method of fabricating the display panel in accordance with one or more embodiments of the present disclosure may include forming the second gate electrode GAT2 (S1200).

The second gate electrode GAT2 may be connected to the first gate electrode GAT1 through a contact hole CNT. The second gate electrode GAT2 may constitute the second node N2 (e.g., see FIG. 3).

The method of fabricating the display panel in accordance with one or more embodiments of the present disclosure may include forming the first interlayer insulating layer ILD1 (S1300).

The first interlayer insulating layer ILD1 may cover the entireties of the second gate electrode GAT2 and the second gate insulating layer GI2.

The method of fabricating the display panel in accordance with one or more embodiments of the present disclosure may include forming the second active pattern ACT2 (S1400).

The second active pattern ACT2 may be formed of an N-type semiconductor layer. At the forming of the second active pattern ACT2, a process of doping N-type impurities may be performed. The second active pattern ACT2 may constitute each of the semiconductor layer of the third transistor TR3 and the semiconductor layer of the fourth transistor TR4 (e.g., see FIG. 3).

The method of fabricating the display panel in accordance with one or more embodiments of the present disclosure may include forming the third gate insulating layer GI3 (S1500).

The third gate insulating layer GI3 may cover the entireties of the second active pattern ACT2 and the first interlayer insulating layer ILD1.

The method of fabricating the display panel in accordance with one or more embodiments of the present disclosure may include forming the third gate electrode GAT3 (S1600).

The third gate electrode GAT3 may be positioned to overlap with at least a portion of the second active pattern ACT2 (e.g., in the third direction DR3). The third gate electrode GAT3 may constitute the gate electrode of the third transistor TR3 and the gate electrode of the fourth transistor TR4.

The method of fabricating the display panel in accordance with one or more embodiments of the present disclosure may include forming the second interlayer insulating layer ILD2 (S1700).

The second interlayer insulating layer ILD2 may cover the entireties of the third gate electrode GAT3 and the third gate insulating layer GI3.

The method of fabricating the display panel in accordance with one or more embodiments of the present disclosure may include forming the first source/drain electrode SD1 (S1800).

The first source/drain electrode SD1 may constitute the second sub-gate line SGL2. The first source/drain electrode SD1 constituting the second sub-gate line SGL2 may be connected, through a contact hole, to the third gate electrode GAT3 that constitutes the gate electrode of the third transistor TR3.

The first source/drain electrode SD1 may constitute the third sub-gate line SGL3. The first source/drain electrode SD1 constituting the third sub-gate line SGL3 may be connected, through a contact hole, to the third gate electrode GAT3 that constitutes the gate electrode of the fourth transistor TR4.

The first source/drain electrode SD1 may constitute the second node N2. The first source/drain electrode SD1 constituting the second node N2 may be connected to the second active pattern ACT3 constituting the semiconductor layer of the third transistor TR3, the second active pattern ACT3 constituting the semiconductor layer of the fourth transistor TR4, and the second gate electrode GAT2 connected to the gate electrode of the first transistor TR1, through respective contact holes.

The first source/drain electrode SD1 may constitute the first node N1. The first source/drain electrode SD1 constituting the first node N1 may be connected, through a contact hole, to the second active pattern ACT2 that constitutes the semiconductor layer of the third transistor TR3. The first source/drain electrode SD1 constituting the first node N1 may be connected, through a contact hole, to the first active pattern ACT1 that constitutes the semiconductor layer of the first transistor TR1.

The first source/drain electrode SD1 may constitute a first side electrode of the fourth transistor TR4 (e.g., an electrode to which the first initialization voltage VINT is applied). The first source/drain electrode SD1 constituting the first side electrode of the fourth transistor TR4 may be connected, through a contact hole, to the second active pattern ACT2 that constitutes the semiconductor layer of the fourth transistor TR4.

In an embodiment, the second and third sub-gate lines SGL2 and SGL3 may be directly formed on the substrate SUB. In the present embodiment, the first source/drain electrode SD1 may be formed as a connection electrode that connects the second active pattern ACT2 and the second and third sub-gate lines SGL2 and SGL3 that are directly formed on the substrate SUB.

The first and fourth sub-gate lines SGL1 and SGL4 and the emission control line ELi (e.g., see FIG. 3) may be configured of the first source/drain electrode SD1 in the same or substantially the same manner as those of the second and third sub-gate lines SGL2 and SGL3. However, in an embodiment, at least one configuration from among the first and fourth sub-gate lines SGL1 and SGL4 and/or the emission control line ELi may be directly formed on the substrate SUB.

The method of fabricating the display panel in accordance with one or more embodiments of the present disclosure may include forming the first via layer VIA1 (S1900).

The first via layer VIA1 may cover the entireties of the first source/drain electrode SD1 and the second interlayer insulating layer ILD2.

The method of fabricating the display panel in accordance with one or more embodiments of the present disclosure may include forming the second source/drain electrode SD2 (S2000).

The second source/drain electrode SD2 may constitute the first node N1.

The second source/drain electrode SD2 constituting the first node N1 may be connected to the first source/drain electrode SD1 (e.g., the first source/drain electrodes SD1) constituting the first node N1 through a contact hole.

The second source/drain electrode SD2 may constitute the third power line PL3. The second source/drain electrode SD2 may be connected to the first source/drain electrode SD1 constituting the first side electrode of the fourth transistor TR4 through a contact hole.

In an embodiment, the third power line PL3 may be directly formed on the substrate SUB. In the present embodiment, the first source/drain electrode SD1 may be formed as a connection electrode that connects the second active pattern ACT2 and the third power line PL3 that is directly formed on the substrate SUB. The second source/drain electrode SD2 may be formed as a connection electrode that connects the first source/drain electrode SD1 and the third power line PL3 that is directly formed on the substrate SUB.

The first, second, and fourth power lines PL1, PL2, and PL4 and the data line DLj (e.g., see FIG. 3) may be configured of the second source/drain electrode SD2 in the same or substantially the same manner as that of the third power line PL3. However, in an embodiment, at least one configuration from among the first, second, and fourth power lines PL1, PL2, and PL4 and/or the data line DLj may be directly formed on the substrate SUB.

The method of fabricating the display panel in accordance with one or more embodiments of the present disclosure may include forming the second via layer VIA2 (S2100).

The second via layer VIA2 may cover the entireties of the second source/drain electrode SD2 and the first via layer VIA1.

The method of fabricating the display panel in accordance with one or more embodiments of the present disclosure may further include forming the light-emitting-element layer LDL (e.g., refer to FIG. 7) on the second via layer VIA2.

According to the method of fabricating the display panel in accordance with one or more embodiments of the present disclosure, a transistor including a single-crystalline silicon semiconductor and a transistor including a metal oxide semiconductor may be formed on the substrate SUB.

Because the transistor including the single-crystalline silicon semiconductor is formed, the surface area of the sub-pixel circuit SPC (e.g., refer to FIG. 3) may be reduced. Accordingly, the number of sub-pixels disposed per unit surface area may be increased. As a result, a high-resolution display device 100 (e.g., refer to FIG. 1) may be provided.

Because the transistor including the metal oxide semiconductor is formed, a leakage current may be reduced. As a result, the display device 100 (e.g., refer to FIG. 1) may be improved in display quality.

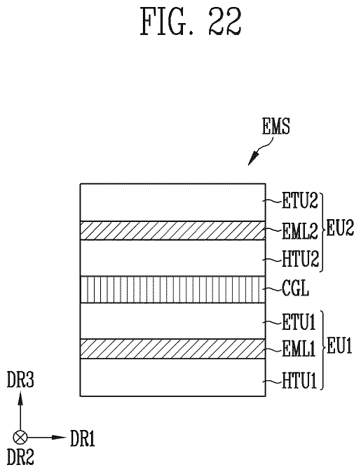

FIG. 22 is a cross-sectional view illustrating an embodiment of the emission structure EMS of FIG. 7.

Referring to FIG. 22, the emission structure EMS may have a tandem structure in which first and second emission components EU1 and EU2 are stacked.

Each of the first and second emission components EU1 and EU2 may include at least one emission layer to generate light in response to a current applied thereto. The first emission component EU1 may include a first emission layer EML1, a first electron transport component ETU1, and a first hole transport component HTU1. The first emission layer EML1 may be disposed between the first electron transport component ETU1 and the first hole transport component HTU1. The second emission component EU2 may include a second emission layer EML2, a second electron transport component ETU2, and a second hole transport component HTU2. The second emission layer EML2 may be disposed between the second electron transport component ETU2 and the second hole transport component HTU2.

Each of the first and second hole transport components HTU1 and HTU2 may include at least one of a hole injection layer and/or a hole transport layer. In an embodiment, each of the first and second hole transport components HTU1 and HTU2 may further include a functional layer, such as a hole buffer layer or an electron blocking layer. The first and second hole transport components HTU1 and HTU2 may have the same or substantially the same configuration as each other, but the present disclosure is not limited thereto, and in some embodiments, may have different configurations from each other.

Each of the first and second electron transport components ETU1 and ETU2 may include at least one of an electron injection layer and/or an electron transport layer. In an embodiment, each of the first and second electron transport components ETU1 and ETU2 may further include a functional layer, such as an electron buffer layer or a hole blocking layer. The first and second electron transport components ETU1 and ETU2 may have the same or substantially the same configuration with each other, but the present disclosure is not limited thereto, and in some embodiments, may have different configurations from each other.

A connection layer may connect the first emission component EU1 and the second emission component EU2 to each other. The connection layer may be provided in the form of a charge generation layer CGL. In one or more embodiments, the charge generation layer CGL may have a stacked structure including a p-type dopant layer and an n-type dopant layer. For example, the p-type dopant layer may include a p-type dopant, such as HAT-CN, TCNQ, or NDP-9. For example, the n-type dopant layer may include an alkali metal, an alkaline earth metal, a lanthanide metal, or a suitable combination thereof. However, the present disclosure is not limited thereto.

In one or more embodiments of the present disclosure, the first emission layer EML1 and the second emission layer EML2 may generate light in different colors (e.g., different wavelength bands) from each other. The light emitted from the first emission layer EML1 and the light emitted from the second emission layer EML2 may be mixed with each other to be visible to a user as white light. For example, the first emission layer EML1 may generate light in a blue color, and the second emission layer EML2 may generate light in a yellow color. In some embodiments, the second emission layer EML2 may include a structure in which a first sub-emission layer to generate light in a red color and a second sub-emission layer to generate light in a green color are stacked. Light in red and light in green may be mixed with each other to allow the second emission layer EML2 to provide light in a yellow color. In this case, an intermediate layer to perform functions of transporting holes and/or blocking the transport of electrons may be further disposed between the first and second sub-emission layers.

In some embodiments, the first emission layer EML1 and the second emission layer EML2 may generate light in the same or substantially the same color as each other.

The emission structure EMS may be formed through a suitable scheme or method, such as vacuum deposition, inkjet printing, or the like, but the present disclosure is not limited thereto.

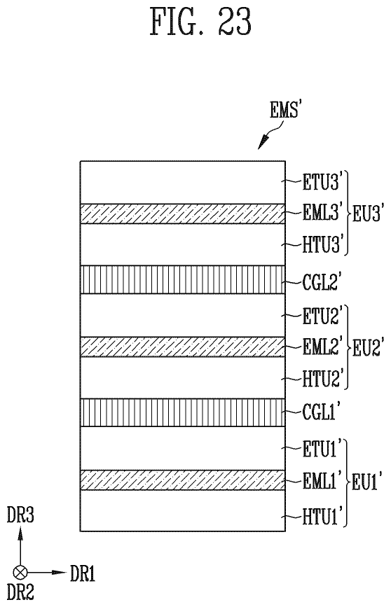

FIG. 23 is a cross-sectional view illustrating another embodiment of the emission structure EMS of FIG. 7.

Referring to FIG. 23, an emission structure EMS' may have a tandem structure in which first to third emission components EU1′ and EU3′ are stacked.

Each of the first to third emission components EU1′ to EU3′ may include an emission layer to generate light in response to a current applied thereto. The first emission component EU1′ may include a first emission layer EML1′, a first electron transport component ETU1′, and a first hole transport component HTU1′. The first emission layer EML1′ may be disposed between the first electron transport component ETU1′ and the first hole transport component HTU1′. The second emission component EU2′ may include a second emission layer EML2′, a second electron transport component ETU2′, and a second hole transport component HTU2′. The second emission layer EML2′ may be disposed between the second electron transport component ETU2′ and the second hole transport component HTU2′. The third emission component EU3′ may include a third emission layer EML3′, a third electron transport component ETU3′, and a third hole transport component HTU3′. The third emission layer EML3′ may be disposed between the third electron transport component ETU3′ and the third hole transport component HTU3′.

Each of the first to third hole transport components HTU1′ and HTU3′ may include at least one of a hole injection layer and/or a hole transport layer. In an embodiment, each of the first to third hole transport components HTU1′ to HTU3′ may further include at least one of a hole buffer layer and/or an electron blocking layer. In an embodiment, the first to third hole transport components HTU1′ to HUT3′ may have the same or substantially the same configuration as each other. However, the present disclosure is not limited thereto. In some embodiments, the first to third hole transport components HTU1′ to HUT3′ may have different configurations from each other.

Each of the first to third electron transport components ETU1′ to ETU3′ may include at least one of an electron injection layer and/or an electron transport layer. In an embodiment, each of the first to third electron transport components ETU1′ to ETU3′ may further include at least one of an electron buffer layer and/or a hole blocking layer. In an embodiment, the first to third electron transport components ETU1′ to ETU3′ may have the same or substantially the same configuration as each other. However, the present disclosure is not limited thereto. In some embodiments, the first to third electron transport components ETU1′ to ETU3′ may have different configurations from each other.

A first charge generation layer CGL1′ may be disposed between the first emission component EU1′ and the second emission component EU2′. A second charge generation layer CGL2′ may be disposed between the second emission component EU2′ and the third emission component EU3′.

In one or more embodiments of the present disclosure, the first to third emission layers EML1′ to EML3′ may generate light in different colors (e.g., different wavelength bands) from each other. Light emitted from the first to third emission layers EML1′ to EML3′ may be mixed with each other to be visible to the user as white light. For example, the first emission layer EML1′ may generate light in a first wavelength band (e.g., a blue color). The second emission layer EML2′ may generate light in a second wavelength band (e.g., a green color). The third emission layer EML3′ may generate light in a third wavelength band (e.g., a red color).

In other embodiments, two or more emission layers from among the first to third emission layers EML1′ to EML3′ may generate light in the same or substantially the same wavelength band (e.g., the same or substantially the same color) as each other.

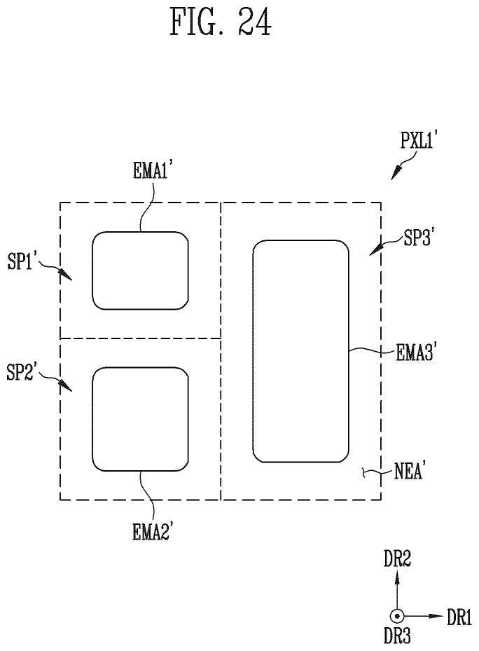

FIG. 24 is a plan view illustrating another embodiment of any one pixel PXL of FIG. 5.

Referring to FIG. 24, a first pixel PXL1′ may include first to third sub-pixels SP1′ to SP3′.

The first sub-pixel SP1′ may include a first emission area EMA1′, and a non-emission area NEA′ formed around (e.g., a periphery of) the first emission area EMA1′. The second sub-pixel SP2′ may include a second emission area EMA2′, and a non-emission area NEA′ formed around (e.g., a periphery of) the second emission area EMA2′. The third sub-pixel SP3′ may include a third emission area EMA3′, and a non-emission area NEA′ formed around (e.g., a periphery of) the third emission area EMA3′.

The first sub-pixel SP1′ and the second sub-pixel SP2′ may be arranged along the second direction DR2 (e.g., may be adjacent to each other in the second direction DR2). The third sub-pixel SP3′ may be disposed in the first direction with respect to each of the first and second sub-pixels SP1′ and SP2′ (e.g., may be adjacent thereto in the first direction).

The surface area of the second sub-pixel SP2′ may be greater than the surface area of the first sub-pixel SP1′. The surface area of the third sub-pixel SP3′ may be greater than the surface area of the second sub-pixel SP2′. The surface area of the second emission area EMA2′ that is the emission area of the second sub-pixel SP2′ may be greater than the surface area of the first emission area EMA1′ that is the emission area of the first sub-pixel SP1′. The surface area of the third emission area EMA3′ that is the emission area of the third sub-pixel SP3′ may be greater than the surface area of the second emission area EMA2′ that is the emission area of the second sub-pixel SP2′. However, the present disclosure is not limited thereto. For example, the surface areas of the first and second sub-pixels SP1′ and SP2′ may be the same or substantially the same as each other. The surface area of the third sub-pixel SP3′ may be greater than the surface area of each of the first and second sub-pixels SP1′ and SP2′. The surface areas of each of the first to third sub-pixels SP1′ to SP3′ may be variously modified as needed or desired depending on embodiments.

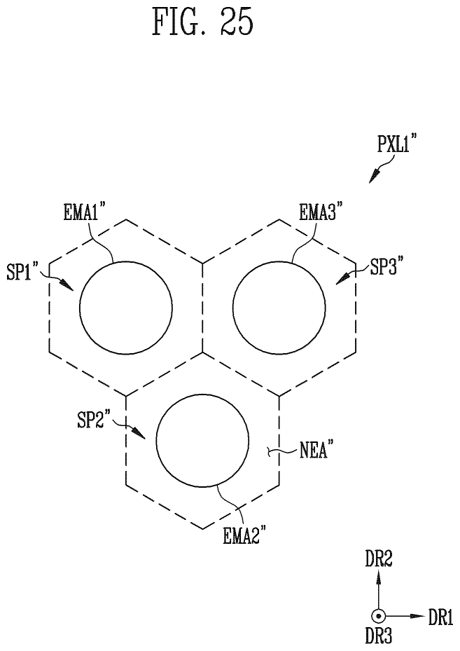

FIG. 25 is a plan view illustrating another embodiment of any one pixel PXL of FIG. 5.

Referring to FIG. 25, a first pixel PXL1″ may include first to third sub-pixels SP1″ to SP3″. The first sub-pixel SP1″ may include a first emission area EMA1″, and a non-emission area NEA″ formed around (e.g., a periphery of) the first emission area EMA1″. The second sub-pixel SP2″ may include a second emission area EMA2″, and a non-emission area NEA″ formed around (e.g., a periphery of) the second emission area EMA2″. The third sub-pixel SP3″ may include a third emission area EMA3″, and a non-emission area NEA″ formed around (e.g., a periphery of) the third emission area EMA3″.

Each of the first to third sub-pixels SP1″ to SP3″ may have a polygonal shape when viewed in one direction (e.g., in the third direction DR3). For example, the shape of each of the first to third sub-pixels SP1″ to SP3″ may be hexagonal (e.g., in a plan view), as illustrated in FIG. 25.

Each of the first to third emission areas EMA1″ to EMA3″ may have a circular shape when viewed in one direction (e.g., in the third direction DR3). However, the present disclosure is not limited thereto. For example, each of the first to third emission areas EMA1″ to EMA3″ may have a polygonal shape.

The first and third sub-pixels SP1″ and SP3″ may be arranged along the first direction DR1 (e.g., may be adjacent to each other in the first direction DR1). The second sub-pixel SP2″ may be disposed in a direction (e.g., a diagonal direction) inclined at an acute angle based on the second direction DR2 with respect to the first sub-pixel SP1″.

The arrangements of the sub-pixels SP illustrated in FIGS. 6, 24, and 25 are illustrative, and the present disclosure is not limited thereto. Each pixel PXL may include two or more sub-pixels SP. The sub-pixels SP in the pixel PXL may be arranged in various suitable ways. Each of the sub-pixels SP may have various suitable shapes. The emission area EMA of the sub-pixel SP may also have various suitable shapes.

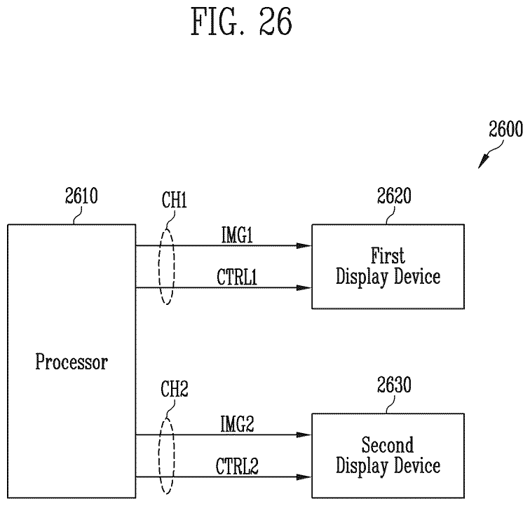

FIG. 26 is a diagram illustrating an example of a display system 2600 in accordance with one or more embodiments of the present disclosure.

Referring to FIG. 26, the display system 2600 may include a processor 2610, and one or more display devices 2620 and 2630.

The processor 2610 may perform various tasks and operations. In one or more embodiments, the processor 2610 may include an application processor (AP), a graphics processing unit (GPU), a microprocessor, a central processing unit (CPU), and/or the like. The processor 2610 may be connected to the other components of the display system 2600 through a bus system to control the components.

In FIG. 26, a case in which the display system 2600 includes the first and second display devices 2620 and 2630 is illustrated. The processor 2610 may be connected to the first display device 2620 through a first channel CH1, and may be connected to the second display device 2630 through a second channel CH2.

The processor 2610 may transmit first image data IMG1 and a first control signal CTRL1 to the first display device 2620 through the first channel CH1. The first display device 2620 may display an image based on the first image data IMG1 and the first control signal CTRL1. The first display device 2620 may be configured in the same or substantially the same manner as that of the display device 100 described above with reference to FIG. 1. In this case, the first image data IMG1 and the first control signal CTRL1 may be provided as the input image data IMG and the control signal CTRL (e.g., see FIG. 1), respectively.

The processor 2610 may transmit second image data IMG2 and a second control signal CTRL2 to the second display device 2630 through the second channel CH2. The second display device 2630 may display an image based on the second image data IMG2 and the second control signal CTRL2. The second display device 2630 may be configured in the same or substantially the same manner as that of the display device 100 described above with reference to FIG. 1. In this case, the second image data IMG2 and the second control signal CTRL2 may be provided as the input image data IMG and the control signal CTRL (e.g., see FIG. 1), respectively.

The display system 2600 may include computing systems that provide an image display function, such as a portable computer, a mobile phone, a smart phone, a tablet personal computer (tablet PC), a smart watch, a watch phone, a portable multimedia player, a navigation system, and an ultra mobile personal computer (UMPC). Furthermore, the display system 2600 may include at least one of a head-mounted display (HMD), a virtual reality (VR) device, a mixed reality (MR) device, and/or an augmented reality (AR) device.

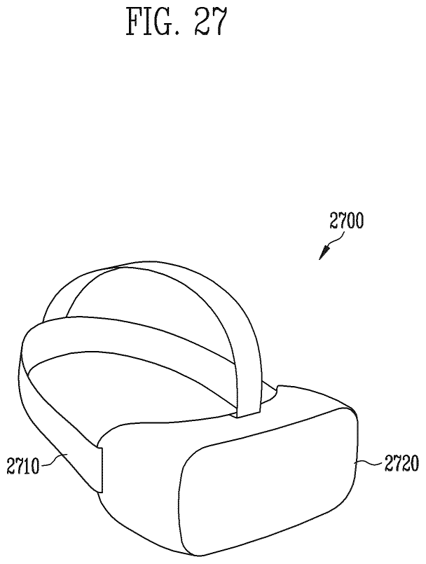

FIG. 27 is a perspective view illustrating an application example of the display system 2600 of FIG. 26.

Referring to FIG. 27, the display system 2600 (e.g., see FIG. 26) may be applied to a head-mounted display 2700. The head-mounted display 2700 may be a wearable electronic device, which may be worn on the head of the user.

The head-mounted display 2700 may include a head-mounted band 2710 and a display device reception casing 2720. The head-mounted band 2710 may be connected to the display device reception casing 2720. The head-mounted band 2710 may include a horizontal band and/or a vertical band to fasten the head-mounted display 2700 to the head of the user. The horizontal band may enclose the sides of the head of the user, and the vertical band may enclose the top of the head of the user. However, the present disclosure is not limited thereto. For example, the head-mounted band 2710 may be implemented in the form of eyeglass frames, a helmet, and the like.

The display device reception casing 2720 may receive the first and second display devices 2620 and 2630 (e.g., see FIG. 26). The display device reception casing 2720 may further receive the processor 2610 (e.g., see FIG. 26).

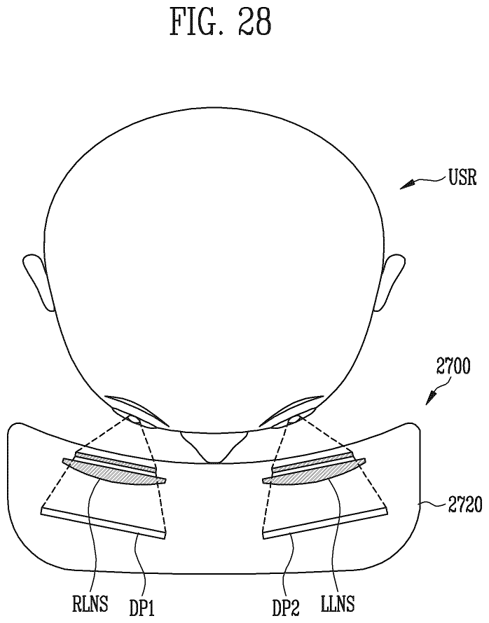

FIG. 28 is a diagram illustrating the head-mounted display 2700 that is worn on the user USR.

Referring to FIG. 28, the first display panel DP1 of the first display device 2620 (e.g., refer to FIG. 26) and the second display panel DP2 of the second display device 2630 (e.g., refer to FIG. 26) are disposed in the head-mounted display 2700. The head-mounted display 2700 may further include one or more lenses. For example, the head-mounted display 2700 may include a left-eye lens LLNS and a right-eye lens RLNS.

In the display device reception casing 2720, the right-eye lens RLNS may be positioned between the first display panel DP1 and the right eye of the user USR. In the display device reception casing 2720, the left-eye lens LLNS may be positioned between the second display panel DP2 and the left eye of the user USR.

An image output from the first display panel DP1 may be viewed by the right eye of the user USR through the right-eye lens RLNS. The right-eye lens RLNS may refract light emitted from the first display panel DP1 toward the right eye of the user USR. The right-eye lens RLNS may perform an optical function to adjust a viewing distance between the first display panel DP1 and the right eye of the user USR.

An image output from the second display panel DP2 may be viewed by the left eye of the user USR through the left-eye lens LLNS. The left-eye lens LLNS may refract light emitted from the second display panel DP2 toward the left eye of the user USR. The left-eye lens LLNS may perform an optical function to adjust a viewing distance between the second display panel DP2 and the left eye of the user USR.

In one or more embodiments, each of the right-eye lens RLNS and the left-eye lens LLNS may include an optical lens having a pancake-shaped cross-section. In one or more embodiments, each of the right-eye lens RLNS and the left-eye lens LLNS may include a multi-channel lens including sub-areas having different optical characteristics. In the present embodiment, the first and second display panels DP1 and DP2 may output images corresponding to sub-areas of the multi-channel lens, respectively. The outputted images may pass through the corresponding sub-areas and be viewed to the user USR.

In a sub-pixel, a display panel including the sub-pixel, and a method of fabricating the display panel in accordance with one or more embodiments of the present disclosure, images may be displayed at various frame rates with a high resolution and reduced power consumption.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display panel comprising:
a silicon substrate;
a first active pattern comprising a single-crystalline semiconductor layer on the silicon substrate;
a first gate insulating layer covering the first active pattern;
a first gate electrode on the first gate insulating layer, and comprising at least a portion overlapping with the first active pattern;
a first interlayer insulating layer on the first gate electrode;
a second active pattern on the first interlayer insulating layer, and comprising a metal oxide semiconductor;
a second gate insulating layer covering the second active pattern;
a second gate electrode on the second gate insulating layer, and comprising at least a portion overlapping with the second active pattern;
a second interlayer insulating layer covering the second gate electrode; and
a source/drain electrode layer on the second interlayer insulating layer, and connected to the first and second active patterns.

2. The display panel according to claim 1, wherein the silicon substrate comprises a buffer layer comprising silicon oxide, and
wherein the first active pattern is located on the buffer layer.

3. The display panel according to claim 1, wherein the first active pattern is part of a semiconductor of a P-type transistor, and the second active pattern is part of a semiconductor of an N-type transistor.

4. The display panel according to claim 1,
wherein the display panel comprises a plurality of sub-pixels, and each of the plurality of sub-pixels comprises at least one light emitting element,
wherein at least one of the plurality of sub-pixels further comprises:
a driving transistor comprising a semiconductor layer, a first electrode connected to a first node, a gate electrode connected to a second node, and a second electrode connected to a third node, the driving transistor being configured to control a magnitude of a current flowing through the light emitting element based on a voltage applied to the second node; and
a compensation transistor comprising a semiconductor layer, and configured to switch an electrical connection between the first node and the second node, and
wherein the semiconductor layer of the driving transistor comprises the first active pattern, and the semiconductor layer of the compensation transistor comprises the second active pattern.

5. The display panel according to claim 4, wherein a gate electrode of the compensation transistor is connected to a sub-gate line.

6. The display panel according to claim 5, wherein the sub-gate line comprises the source/drain electrode layer.

7. The display panel according to claim 5,
wherein the sub-gate line is directly located on the silicon substrate, and
wherein the source/drain electrode layer comprises a connection electrode configured to electrically connect the sub-gate line and the second active pattern to each other.

8. The display panel according to claim 4,
wherein the at least one of the plurality of sub-pixels further comprises an initialization transistor comprising a semiconductor layer, and configured to switch an electrical connection between the second node and a power line configured to be applied with an initialization voltage, and
wherein the semiconductor layer of the initialization transistor comprises the second active pattern.

9. The display panel according to claim 8, wherein a gate electrode of the initialization transistor is connected to a sub-gate line.

10. The display panel according to claim 9, wherein the sub-gate line comprises the source/drain electrode layer.

11. The display panel according to claim 9,
wherein the sub-gate line is directly located on the silicon substrate, and
wherein the source/drain electrode layer comprises a connection electrode configured to electrically connect the sub-gate line and the second active pattern to each other.

12. The display panel according to claim 8,
wherein the source/drain electrode layer comprises a first source/drain electrode layer, and
wherein the display panel comprises:
a first via layer covering the first source/drain electrode layer;
a second source/drain electrode layer on the first via layer, and connected to the first source/drain electrode layer through a contact hole; and
a second via layer covering the second source/drain electrode layer.

13. The display panel according to claim 12, wherein the power line comprises the second source/drain electrode layer.

14. The display panel according to claim 8,
wherein the power line is directly located on the silicon substrate, and
wherein the source/drain electrode layer comprises a connection electrode configured to electrically connect the power line and the second active pattern to each other.

15. A sub-pixel comprising:
a light emitting element; and
a sub-pixel circuit configured to supply a current to the light emitting element,
wherein the sub-pixel circuit comprises:
a driving transistor comprising a first active pattern having a single-crystalline structure on a silicon substrate and connected to a first node and a third node, and a first gate electrode connected to a second node and comprising at least a portion overlapping with the first active pattern, the driving transistor being configured to provide a current corresponding to a voltage applied to the second node; and
a compensation transistor comprising a second active pattern comprising a metal oxide semiconductor layer, and a second gate electrode comprising at least a portion overlapping with the second active pattern, the compensation transistor being configured to switch an electrical connection between the first node and the second node.

16. The sub-pixel according to claim 15, wherein the first active pattern is part of a semiconductor of a P-type transistor, and the second active pattern is part of a semiconductor of an N-type transistor.

17. A method of fabricating a display panel, comprising:
forming a first active pattern having a single-crystalline structure on a silicon substrate;
forming a first gate insulating layer on the first active pattern;
forming a first gate electrode comprising at least a portion overlapping with the first active pattern;
forming a first interlayer insulating layer on the first gate electrode;
forming a second active pattern comprising a metal oxide semiconductor on the first interlayer insulating layer;
forming a second gate insulating layer on the second active pattern;
forming, on the second gate insulating layer, a second gate electrode comprising at least a portion overlapping with the second active pattern;
forming a second interlayer insulating layer on the second gate electrode; and
forming, on the second interlayer insulating layer, a source/drain electrode layer connected to the first and second active patterns.

18. The method according to claim 17, further comprising forming a buffer layer by injecting oxygen ions into the silicon substrate,
wherein the first active pattern is formed on the buffer layer.

19. The method according to claim 18,
wherein the forming of the first active pattern comprises doping a P-type impurity, and
wherein the forming of the second active pattern comprises doping an N-type impurity.

20. The method according to claim 18, further comprising directly forming a power line or a sub-gate line on the silicon substrate,
wherein the forming of the source/drain electrode layer comprises at least one of:
connecting the second active pattern and the power line to each other; or
connecting the second active pattern and the sub-gate line to each other.
